(19) United States
(12) Patent Application Publication
(10) Pub. No.: US 2024/0064962 A1
(43) Pub. Date: Feb. 22, 2024

(54) DOPED DIELECTRIC MATERIAL

(71) Applicant: Micron Technology, Inc., Boise, ID (US)

(72) Inventors: David K. Hwang, Boise, ID (US); Litao Yang, Boise, ID (US)

(21) Appl. No.: 17/889,384

(22) Filed: Aug. 16, 2022

(51) Int. Cl. H01L 27/108; H01L 29/423; H01L 29/08; H01L 29/167

(52) U.S. Cl. CPC H01L 27/10811; H01L 27/10873; H01L 29/42392; H01L 29/0847; H01L 29/167

(57) ABSTRACT

Systems, methods and apparatus are provided for three-dimensional memory devices, including an array of vertically stacked memory cells having: access devices each respectively including: a semiconductor material comprising a first source/drain region and a second source/drain region separated by a respective channel region, and a respective gate opposing the respective channel region and separated therefrom by a respective gate dielectric; a respective first doped dielectric material adjacent to the respective gate and the respective semiconductor material; and a respective second doped dielectric material adjacent to the respective gate and the respective semiconductor material, wherein the respective second doped dielectric material is opposite to the respective first doped dielectric material relative to the respective gate; storage nodes electrically coupled to the respective second source/drain regions of the access devices.

### TECHNICAL FIELD

The present disclosure relates generally to memory devices, and more particularly, to vertical three-dimensional (3D) memory having a doped dielectric material.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

A respective memory cell for DRAM may include an access device, e.g., transistor, having a first and a second source/drain regions separated by channel regions. A gate may oppose the channel region and be separated therefrom by a gate dielectric. An access line, such as a word line, is electrically connected to the gate of the DRAM cell. A DRAM cell can include a storage node, such as a capacitor cell, coupled by the access device to a digit line. The access device can be activated (e.g., to select the cell) by an access line coupled to the access transistor. The capacitor can store a charge corresponding to a data value of a respective cell (e.g., a logic “1” or “0”).

### BRIEF DESCRIPTION OF THE DRAWINGS

FIG. 1A is a block diagram of an apparatus in accordance with a number of embodiments of the present disclosure.

FIG. 1B illustrates a perspective view showing a three-dimensional semiconductor memory device in accordance with a number of embodiments of the present disclosure.

FIG. 2A is a block diagram of an apparatus in accordance with a number of embodiments of the present disclosure.

FIG. 2B illustrates a perspective view showing a three-dimensional semiconductor memory device in accordance with a number of embodiments of the present disclosure.

FIG. 3A illustrates a unit cell of the vertically stacked array of memory cells according to some embodiments of the present disclosure.

FIG. 3B illustrates a unit cell of the vertically stacked array of memory cells according to some embodiments of the present disclosure.

FIG. 4 is a cross-sectional view, at one stage of a semiconductor device fabrication process, in accordance with a number of embodiments of the present disclosure.

FIG. 5A illustrates an example method, at one stage of a semiconductor device fabrication process, in accordance with a number of embodiments of the present disclosure.

FIG. 5B is a cross sectional view of a semiconductor structure at one stage of a semiconductor device fabrication process.

FIGS. 6A to 6E illustrate an example method, at a stage of a semiconductor fabrication process, in accordance with a number of embodiments of the present disclosure.

FIGS. 7A to 7D illustrate an example method, at a stage of a semiconductor fabrication process, in accordance with a number of embodiments of the present disclosure.

FIG. 8 illustrates an example method at one stage of a semiconductor device fabrication process in accordance with a number of embodiments of the present disclosure.

FIG. 9A illustrates a cross sectional view of a semiconductor structure at a particular point in the semiconductor device fabrication process.

FIG. 9B illustrates a cross sectional view of a semiconductor structure at a particular point in the semiconductor device fabrication process.

FIGS. 10A to 10C illustrate an example method, at a stage of a semiconductor fabrication process, in accordance with a number of embodiments of the present disclosure.

FIG. 11 illustrates a cross sectional view of a semiconductor structure at a point in the semiconductor device fabrication process.

FIGS. 12A to 12D illustrate an example method, at a stage of a semiconductor device fabrication process.

FIG. 13 illustrates a cross sectional view of the semiconductor structure at a point in the semiconductor device fabrication process.

FIG. 14 illustrates a cross sectional view of a semiconductor structure at a point in one example semiconductor device fabrication process of another alternate embodiment of the present disclosure.

FIG. 15 is a block diagram of an apparatus in the form of a computing system including a memory device in accordance with a number of embodiments of the present disclosure.

### DETAILED DESCRIPTION

Three-dimensional (3D) memory devices can include a number of memory cells in various rows and columns (e.g., the various memory cells can extend both laterally and vertically). Generally, it is desirable that each of the memory cells of a 3D memory device is fabricated to be uniform to one another.

Semiconductor materials, which can be utilized in 3D memory devices, can be modified (e.g., doped) to be majority hole (p-type) or majority electron (n-type) carrier materials. Semiconductor material modification has been done by processes, such as ion implantation or high temperature diffusion. However, as memory devices continue to shrink and as 3D memory devices employ multiple layers, semiconductor material doping by ion implantation or high temperature diffusion can result in non-uniform cells because of the shrinking volumes of semiconductor material to be doped and/or the impeding layers of 3D memory devices. These non-uniform cells can provide inconsistent electrical properties for the 3D memory devices.

Embodiments of the present disclosure describe three-dimensional (3D) memory devices having access devices that utilize a doped dielectric material; this type of doping can be referred to as electrostatic doping. In contrast to semiconductor material doping by ion implantation or high temperature diffusion, embodiments of the present disclosure provide uniform cells. For instance, for ion implantation doping, silicon that is intended to be doped would be blocked by other silicon materials in the cubic structure. These uniform cells can provide consistent electrical properties for the 3D memory devices.

For vertically stacked memory array structures, polycrystalline silicon (also referred to as polysilicon) can be leaky, allowing current to leak through the polycrystalline structure, making the transistor less effective. In contrast, single crystal silicon is less leaky, however, single crystal silicon cannot grow on amorphous dielectric materials, such as oxides or nitrides.

However, as included herein, it is possible to use a silicon wafer for a transistor that can be utilized as a substrate during the high temperature processes required for single crystal silicon formation. In such embodiments, a layer of silicon germanium can be grown on the silicon substrate. Single crystal silicon can, then, be grown on the silicon germanium.

This may be accomplished, for example, by providing a thin single crystal silicon germanium layer, as a seed layer, and then heating the layer to grow the single crystal silicon germanium layer thickness through epitaxial growth. Once the desired layer thickness is formed, a silicon layer can be formed into the surface of the silicon germanium layer. As with the silicon germanium layer, this may be accomplished, for example, by providing a thin single crystal silicon layer, as a seed layer, and then heating the layer to grow the thin single crystal silicon layer thickness into a thicker single crystal silicon layer through epitaxial growth.

Depending on the silicon germanium concentration, if silicon is x quantity and germanium is y quantity and, if y is smaller than x, then silicon/silicon germanium has a small lattice mismatch with respect to the lattice of single crystal silicon. This allows silicon to be grown on top of silicon germanium with a single crystal structure. If a thin layer of single crystal silicon is applied to the surface of the silicon germanium, then the whole silicon layer acts as a seed for the growth of the single crystal silicon layer. Such layering can be done in alternating iterations (e.g., SiGe/Si/SiGe/Si, etc.) to create a superlattice structure in the form of a vertical stack, as illustrated herein.

As an example, a seed layer of silicon germanium can be formed that is 100 Angstroms in thickness (height) and can be grown to, for example 1000 Angstroms. A thin silicon seed layer can be formed on the surface of the silicon germanium layer that is, for example, 50 Angstroms and can be grown to a thickness of, for example, 300 Angstroms. These thicknesses are merely provided as examples and should not be regarded as limiting unless recited explicitly in a particular claim.

The devices of the present disclosure will have better performance with regard to I-on, better I-off, drivability, and/or leakage current because there is no grain boundary and therefore current cannot leak through the grain boundary which is where leakage often occurs in polysilicon. In some embodiments, devices can have, for example, three orders of magnitude lower I-off (leakage).

Advantages to the structure and process described herein can include a lower off-current (Ioff) for the access devices, as compared to silicon based (Si-based) access devices (e.g., transistors), better DRAM refresh requirement, and/or reduced gate/drain induced leakage (GIDL) for the access devices. The present disclosure describes a channel region formed from a epitaxially grown materials. Combined with a gate all around (GAA) structure (e.g., at the channel region of the semiconductor material) provides better electrostatic control on the channel, better subthreshold slope and a more cost-effective process.

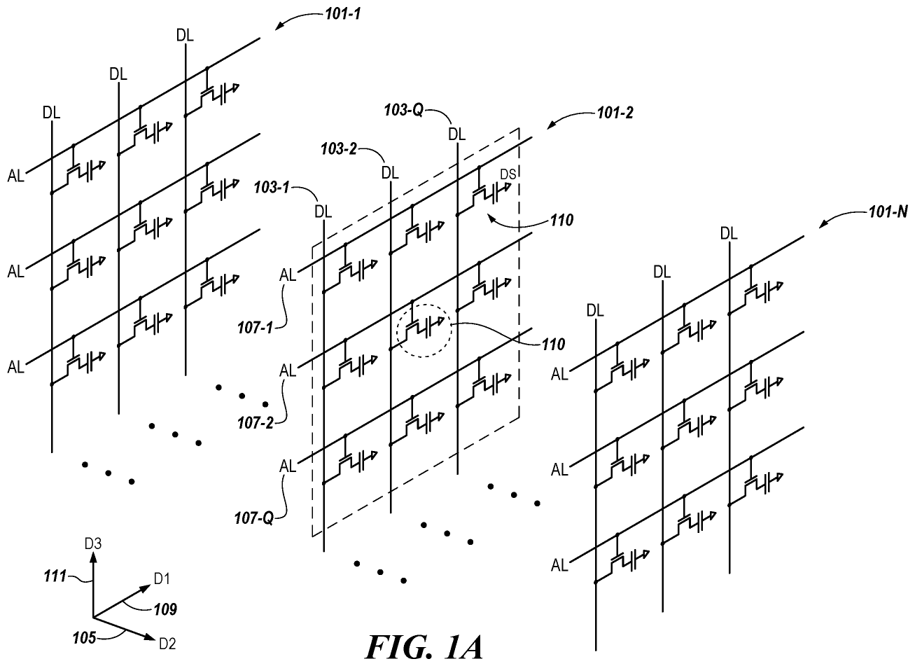

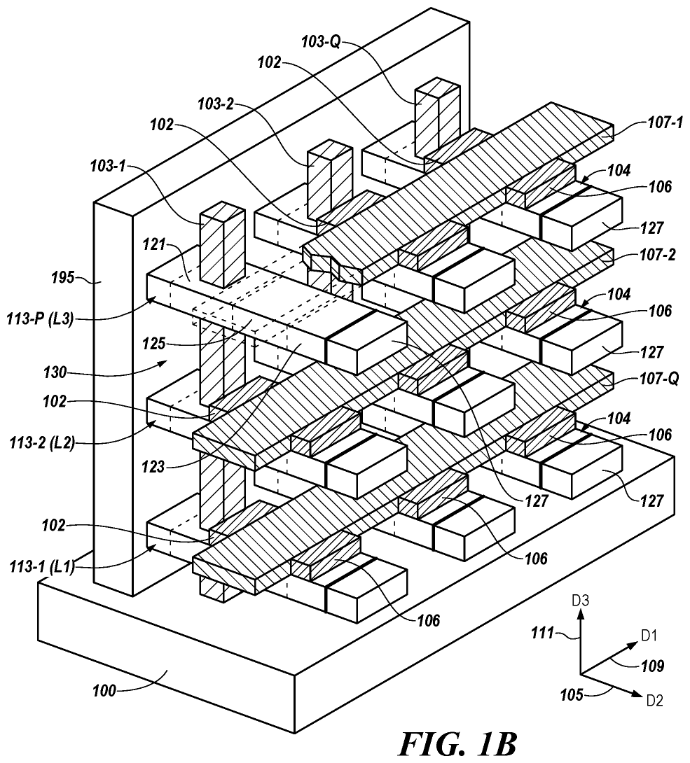

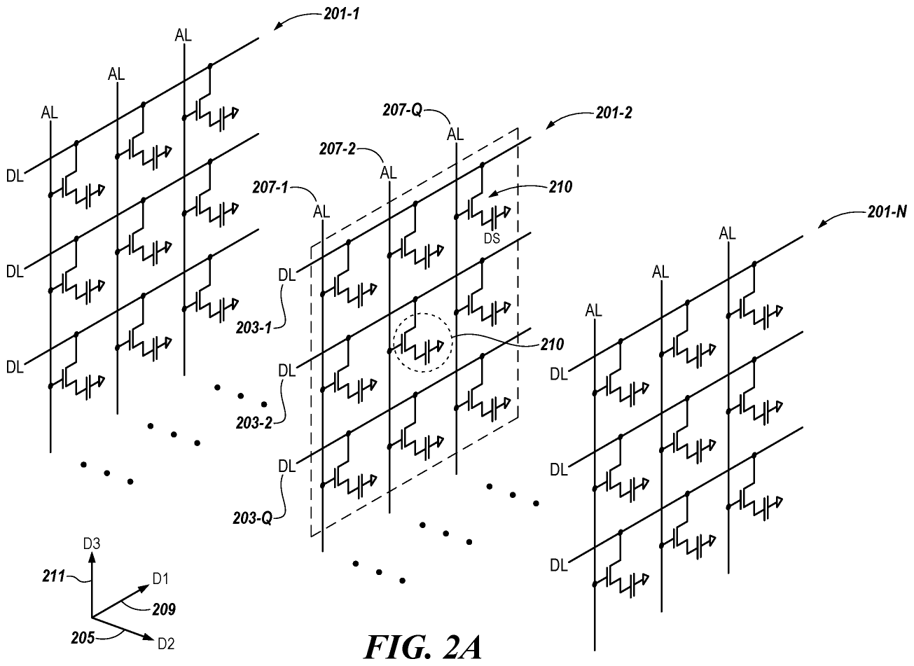

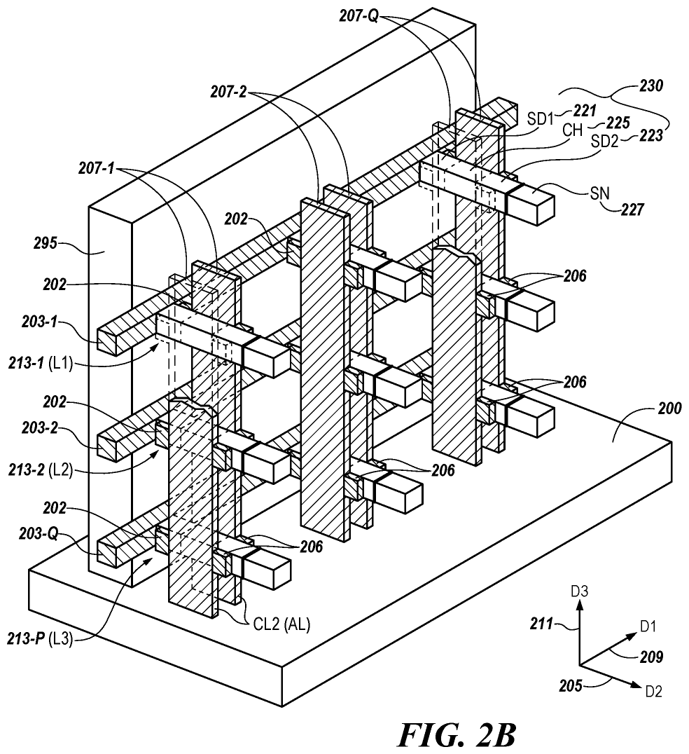

The figures herein follow a numbering convention in which the first digit or digits correspond to the figure number of the drawing and the remaining digits identify an element or component in the drawing. Similar elements or components between different figures may be identified by the use of similar digits. For example, reference numeral 103 may reference element “03” in FIG. 1, and a similar element may be referenced as 203 in FIG. 2. Multiple analogous elements within one figure may be referenced with a reference numeral followed by a hyphen and another numeral or a letter. For example, 431-1 may reference element 431-1 in FIGS. 4 and 431-2 may reference element 431-2, which may be analogous to element 431-1. Such analogous elements may be generally referenced without the hyphen and extra numeral or letter. For example, elements 431-1 and 431-2 or other analogous elements may be generally referenced as 431.

FIG. 1A is a block diagram of an apparatus in accordance with a number of embodiments of the present disclosure. FIG. 1A illustrates a circuit diagram showing a cell array of a three-dimensional (3D) semiconductor memory device according to embodiments of the present disclosure. FIG. 1A illustrates that a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays (e.g., sub cell array 101-2) may include a plurality of access lines 107-1, 107-2, . . . , 107-Q (which also may be referred to a word lines). Also, each of the sub cell arrays (e.g., sub cell array 101-2) may include a plurality of digit lines 103-1, 103-2, . . . , 103-Q (which also may be referred to as bit lines, data lines, or sense lines). In FIG. 1A, the access lines 107-1, 107-2, . . . , 107-Q are illustrated extending in a first direction (D1) 109 and the digit lines 103-1, 103-2, . . . , 103-Q are illustrated extending in a direction (D3) 111. According to embodiments, the first direction (D1) 109 and the second direction (D2) 105 may be considered in a horizontal (“X-Y”) plane. The direction (D3) 111 may be considered in a vertical (“Z”) plane. Hence, according to one or more embodiments described herein, the digit lines 103-1, 103-2, . . . , 103-Q are extending in a vertical direction (e.g., direction (D3) 111).

A memory cell may include an access device (e.g., access transistor) and a storage node located at an intersection of each access line 107-1, 107-2, . . . , 107-Q and each digit line 103-1, 103-2, . . . , 103-Q. Memory cells may be written to, or read from, using the access lines 107-1, 107-2, . . . , 107-Q and digit lines 103-1, 103-2, . . . , 103-Q. The access lines 107-1, 107-2, . . . , 107-Q may conductively interconnect memory cells along horizontal rows of each sub cell array 101-, 101-2, . . . , 101-N, and the digit lines 103-1, 103-2, . . . , 103-Q may conductively interconnect memory cells along vertical columns of each sub cell array 101-, 101-2, . . . , 101-N. One memory cell (e.g. 110) may be located between one access line (e.g., 107-2) and one digit line (e.g., 103-2). Each memory cell may be uniquely addressed through a combination of an access line 107-1, 107-2, . . . , 107-Q and a digit line 103-1, 103-2, . . . , 103-Q.

The access lines 107-1, 107-2, . . . , 107-P may be or include conducting patterns (e.g., metal lines) disposed on and spaced apart from a substrate. The access lines 107-1, 107-2, . . . , 107-Q may extend in a first direction (D1) 109. The access lines 107-1, 107-2, . . . , 107-Q in one sub cell array, e.g., 101-2, may be spaced apart from each other in a vertical direction (e.g., in a direction (D3) 111).

The digit lines 103-1, 103-2, . . . , 103-Q may be or include conductive patterns (e.g., metal lines) extending in a vertical direction with respect to the substrate, e.g., in a direction (D3) 111. The digit lines in one sub cell array (e.g., 101-2) may be spaced apart from each other in the first direction (D1) 109.

A gate of a memory cell (e.g., memory cell 110) may be connected to an access line (e.g., 107-2) and a first conductive node (e.g., first source/drain region) of an access device of the memory cell. Each of the memory cells (e.g., memory cell 110) may be connected to a storage node (e.g., capacitor). A second conductive node (e.g., second source/drain region) of the access device may be connected to the storage node. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line, e.g., 103-2, and the other may be connected to a storage node.

FIG. 1B illustrates a perspective view showing a three dimensional (3D) semiconductor memory device (e.g., a portion of a sub cell array 101-2 shown in FIG. 1A) as a vertically oriented stack of memory cells in an array, according to some embodiments of the present disclosure.

As shown in FIG. 1B, a substrate 100 may have formed thereon one of the plurality of sub cell arrays (e.g., 101-2, shown in FIG. 1A). The substrate 100 may be or include a silicon substrate, a germanium substrate, or a silicon-germanium substrate, etc. Embodiments, however, are not limited to these examples.

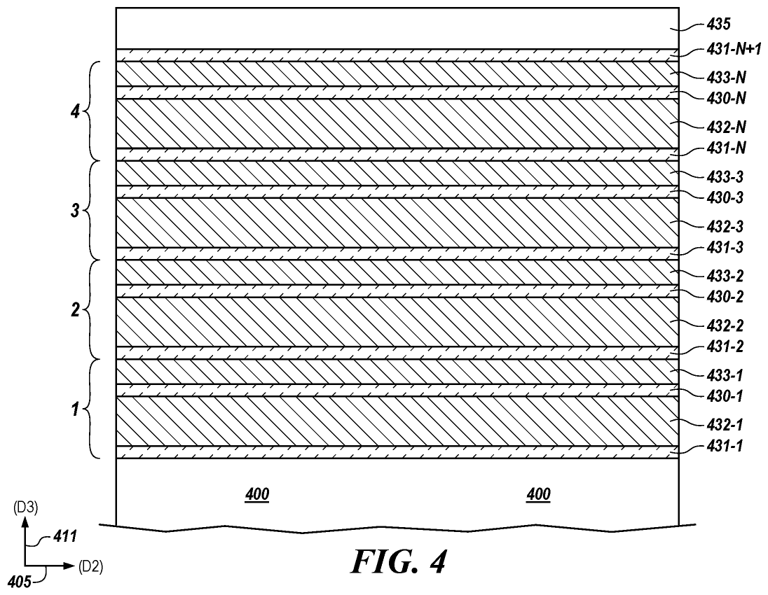

As shown in the example embodiment of FIG. 1B, the substrate 100 may have fabricated thereon a vertically oriented stack of memory cells (e.g., memory cell 110 shown in FIG. 1A) extending in a vertical direction (D3) 111. According to some embodiments the vertically oriented stack of memory cells may be fabricated such that each memory cell is formed on plurality of vertical levels (e.g., a first level (L1), a second level (L2), and a third level (L3). The repeating, vertical levels may be arranged (e.g., stacked) in a vertical direction (D3) 111, and may be separated from the substrate 100 by an insulator material (not shown in FIG. 1B). Each of the repeating, vertical levels may include a plurality of discrete components (e.g., regions) for the horizontally oriented access devices 130 and storage nodes, including access line 107-1, 107-2, . . . , 107-Q connections and digit line 103-1, 103-2, . . . , 103-Q connections. The plurality of discrete components to the access devices 130 may be formed in a plurality of iterations of vertically, repeating layers within each level, as described in more detail below in connection with FIG. 4 and may extend horizontally in the second direction (D2) 105.

The plurality of discrete components to the access devices 130 may include a first source/drain region 121 and a second source/drain region 123 separated by a channel region 125, extending laterally in the second direction (D2) 105. As discussed further herein, a gate dielectric (which may also be referred to as a gate dielectric material) 104 can be formed on (e.g., partially, or completely covering) the first source/drain region 121, the second source/drain region 123, and/or the channel region 125. In some embodiments, the channel region 125 may include silicon, germanium, silicon-germanium, and/or indium gallium zinc oxide (IGZO). In some embodiments, the first and the second source/drain regions, 121 and 123, respectively, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms formed in an oppositely doped body region of polysilicon semiconductor material and the p-type dopant may include atoms of boron (B) formed in an oppositely doped body region of polysilicon semiconductor material. Embodiments, however, are not limited to these examples. One or more embodiments provide that the first source/drain region 121, the second source/drain region 123, and the channel region 125 are formed from a semiconductor material (e.g., silicon). The semiconductor material can be a crystalline silicon material. The semiconductor material can be epitaxially grown silicon. One or more embodiments provide that the semiconductor material (e.g., the first source/drain region 121, the second source/drain region 123, and the channel region 125) is undoped. One or more embodiments provide that the semiconductor material (e.g., the first source/drain region 121, the second source/drain region 123, and the channel region 125) is lightly doped. One or more embodiments provide that the first source/drain region 121, the second source/drain region 123, and the channel region 125 having uniform doping (which may include no doping for each of the source/drain regions and channel regions).

The storage node 127 (shown later as 227, 327), e.g., capacitor, may be connected to the access device 130. As shown in FIG. 1B, the storage node 127 may be connected to the second source/drain region 123 of the access device 130. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell (e.g., memory cell 110 in FIG. 1A) may similarly extend in the second direction (D2) 105.

As shown in FIG. 1B a plurality of horizontally oriented access lines 107-1, 107-2, . . . , 107-Q extend in the first direction (D1) 109. The plurality of horizontally oriented access lines 107-1, 107-2, . . . , 107-Q may be arranged (e.g., stacked) along the direction (D3) 111. The plurality of horizontally oriented access lines 107-1, 107-2, . . . , 107-Q may include a conductive material. For example, the conductive material may include one or more of a doped semiconductor (e.g., doped silicon, doped germanium, etc.), a conductive metal nitride (e.g., titanium nitride, tantalum nitride, etc.), a metal (e.g., tungsten (W), titanium (Ti), tantalum (Ta), ruthenium (Ru), cobalt (Co), molybdenum (Mo), etc.), and/or a metal-semiconductor compound (e.g., tungsten silicide, cobalt silicide, titanium silicide, etc.). Embodiments, however, are not limited to these examples.

Among each of the vertical levels, (L1) 113-1, (L2) 113-2, and (L3) 113-P, the horizontally oriented memory cells may be spaced apart from one another horizontally in the first direction (D1) 109. However, the plurality of discrete components to the horizontally oriented access devices 130 (e.g., first source/drain region 121 and second source/drain region 123 separated by a channel region 125, extending laterally in the second direction (D2) 105, and the plurality of horizontally oriented access lines 107-1, 107-2, . . . , 107-Q extending laterally in the direction (D1) 109) may be formed within different vertical layers within each level. For example, the plurality of horizontally oriented access lines 107-1, 107-2, . . . , 107-Q may be formed on a top surface opposing and electrically coupled to the channel regions 125, separated therefrom by a gate dielectric 104, and orthogonal to horizontally oriented access devices 130 extending in laterally in the second direction (D2) 105. In some embodiments, the plurality of horizontally oriented access lines 107-1, 107-2, . . . , 107-Q, extending in the first direction (D1) 109 are formed in a higher vertical layer, farther from the substrate 100, within a level (e.g., within level (L1)) than a layer in which the discrete components (e.g., first source/drain region 121 and second source/drain region 123 separated by a channel region 125) of the horizontally oriented access device are formed.

As shown in FIG. 1B, a first doped dielectric material 102 (e.g., a first electrostatic doping dielectric material) and a second doped dielectric material 106 (e.g., a second electrostatic doping dielectric material), as discussed further herein, may be utilized. The first doped dielectric material 102 can be adjacent to a gate and a semiconductor material (e.g., the first source/drain region 121). The second doped dielectric material 106 can be adjacent to the gate and a semiconductor material (e.g., the second source/drain region 123).

As shown in FIG. 1B, the digit lines 103-1, 103-2, . . . , 103-Q extend in a vertical direction with respect to the substrate 100 (e.g., direction (D3) 111). Also, the digit lines, 103-1, 103-2, . . . , 103-Q, in one sub cell array (e.g., sub cell array 101-2 in FIG. 1A) may be spaced apart from each other in the direction (D1) 109. The digit lines, 103-1, 103-2, . . . , 103-Q, may be provided, extending vertically relative to the substrate 100 in the direction (D3) 111 in vertical alignment with source/drain regions to serve as first source/drain regions 121 or, as shown, be vertically adjacent first source/drain regions 121 for each of the horizontally oriented access devices 130 extending laterally in the direction (D2) 105, but adjacent to each other on a level (e.g., first level (L1)) in the first direction (D1) 109. Each of the digit lines, 103-1, 103-2, . . . , 103-Q, may vertically extend, in the direction (D3), on sidewalls, adjacent first source/drain regions 121, of respective ones of the plurality of horizontally oriented access devices 130 that are vertically stacked. In some embodiments, the plurality of vertically oriented digit lines 103-1, 103-2, . . . , 103-Q, extending in the direction (D3) 111, may be connected to side surfaces of the first source/drain regions 121 directly and/or through additional contacts including metal silicides.

For example, a first one of the vertically extending digit lines (e.g., 103-1) may be adjacent a sidewall of a first source/drain region 121 to a first one of the horizontally oriented access devices 130 in the level (L1) 113-1, a sidewall of a first source/drain region 121 of a first one of the horizontally oriented access devices 130 in the level (L2) 113-2, and a sidewall of a first source/drain region 121 a first one of the horizontally oriented access devices 130 in the level (L3) 113-P, etc. Similarly, a second one of the vertically extending digit lines (e.g., 103-2) may be adjacent a sidewall to a first source/drain region 121 of a second one of the horizontally oriented access devices 130, in the level (L1) 113-1, spaced apart from the first one of horizontally oriented access devices 130 in the level (L1) 113-1 in the direction (D1) 109. And the second of the vertically extending digit lines (e.g., 103-2) may be adjacent a sidewall of a first source/drain region 121 of a second one of the horizontally (which may be referred to as laterally) oriented access devices 130 in the level (L2) 113-2, and a sidewall of a first source/drain region 121 of a second one of the horizontally oriented access devices 130, e.g., transistors, in the level (L3) 113-P, etc. Embodiments are not limited to a particular number of levels.

The vertically extending digit lines, 103-1, 103-2, . . . , 103-Q, may include a conductive material. For example, the digit lines may include one of a doped semiconductor material, a conductive metal nitride, metal, and/or a metal-semiconductor compound.

As shown in FIG. 1B, a conductive body contact 195 may be formed extending in the direction (D1) 109 along an end surface of the horizontally oriented access devices 130 in each level (L1) 113-1, (L2) 113-2, and (L3) 113-P above the substrate 100. The body contact may be connected to a body (e.g., body region) of the horizontally oriented access devices 130 in each memory cell. The body contact may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2A is a block diagram of an apparatus in accordance with a number of embodiments of the present disclosure. FIG. 2A illustrates a circuit diagram showing a cell array of a three-dimensional (3D) semiconductor memory device according to embodiments of the present disclosure. FIG. 2A illustrates that a cell array may have a plurality of sub cell arrays 201-1, 201-2, . . . , 201-N. The sub cell arrays 201-1, 201-2, . . . , 201-N may be arranged along a direction (D2) 205. Each of the sub cell arrays (e.g., sub cell array 201-2) may include a plurality of access lines 207-1, 207-2, . . . , 207-Q. Also, each of the sub cell arrays (e.g., sub cell array 201-2) may include a plurality of digit lines 203-1, 203-2, . . . , 203-Q. In FIG. 2A, the digit lines 203-1, 203-2, . . . , 203-Q are illustrated extending in a first direction (D1) 209 and the access lines 207-1, 207-2, . . . , 207-Q are illustrated extending in a second direction (D3) 211.

The direction (D1) 209 and the direction (D2) 205 may be considered in a horizontal (“X-Y”) plane. The direction (D3) 211 may be considered in a vertical (“Z”) direction (e.g., transverse to the X-Y plane). Hence, according to embodiments described herein, the access lines 207-1, 207-2, . . . , 207-Q can extend in a vertical direction (e.g., direction (D3) 211).

A memory cell 210 may include an access device and a storage node located at an intersection of each access line 207-1, 207-2, . . . , 207-Q and each digit line 203-1, 203-2, . . . , 203-Q. Memory cells may be written to, or read from, using the access lines 207-1, 207-2, . . . , 207-Q and digit lines 203-1, 203-2, . . . , 203-Q. The digit lines 203-1, 203-2, . . . , 203-Q may conductively interconnect memory cells along horizontal columns of each sub cell array 201-, 201-2, . . . , 201-N, and the access lines 207-1, 207-2, . . . , 207-Q may conductively interconnect memory cells along vertical rows of each sub cell array 201-1, 201-2, . . . , 201-N. One memory cell, e.g., 210, may be located between one access line and one digit line. Each memory cell may be uniquely addressed through a combination of an access line 207-1, 207-2, . . . , 207-Q and a digit line 203-1, 203-2, . . . , 203-Q.

The digit lines 203-1, 203-2, . . . , 203-Q may be or include conducting patterns (e.g., metal lines) disposed on and spaced apart from a substrate. The digit lines 203-1, 203-2, . . . , 203-Q may extend in direction (D1) 209. The digit lines 203-1, 203-2, . . . , 203-Q in one sub cell array (e.g., 201-2) may be spaced apart from each other in a vertical direction (e.g., direction (D3) 211).

The access lines 207-1, 207-2, . . . , 207-Q may be or include conductive patterns (e.g., metal lines) extending in a vertical direction with respect to the substrate (e.g., in direction (D3) 211). The access lines in one sub cell array (e.g., 201-2) may be spaced apart from each other in direction (D1) 209.

A gate of a memory cell (e.g., memory cell 210) may be connected to an access line (e.g., 207-2) and a first conductive node (e.g., first source/drain region) of an access device of the memory cell 210 may be connected to a digit line (e.g., 203-2). Each of the memory cells may be connected to a storage node. A second conductive node (e.g., second source/drain region) of the access device of the memory cell may be connected to the storage node. Storage nodes, such as capacitors, can be formed from ferroelectric and/or dielectric materials such as zirconium oxide (ZrO2), hafnium oxide (HfO2) oxide, lanthanum oxide (La2O3), lead zirconate titanate (PZT, Pb[Zr(x)Ti(1-x)]O3), barium titanate (BaTiO3), aluminum oxide (e.g., Al₂O₃), a combination of these with or without dopants, or other suitable materials.

While first and second source/drain region reference are used herein to denote two separate and distinct source/drain regions, it is not intended that the source/drain region referred to as the “first” and/or “second” source/drain regions have some unique meaning. It is intended only that one of the source/drain regions is connected to a digit line (e.g., 203-2) and the other may be connected to a storage node.

FIG. 2B illustrates a perspective view showing a three dimensional (3D) semiconductor memory device (e.g., a portion of a sub cell array 201-2 shown in FIG. 2A as a vertically oriented stack of memory cells in an array) according to some embodiments of the present disclosure. As shown in FIG. 2B, a substrate 200 may have formed thereon one of the plurality of sub cell arrays (e.g., 201-2) described in connection with FIG. 2A.

As shown in FIG. 2B, the substrate 200 may have fabricated thereon a vertically oriented stack of memory cells extending in a vertical direction (e.g., direction (D3) 211). According to some embodiments the vertically oriented stack of memory cells may be fabricated such that each memory cell is formed on plurality of vertical levels (e.g., a first level (L1), a second level (L2), and/or a third level (L3)). The repeating, vertical levels, L1, L2, and L3, may be arranged a vertical direction (e.g., direction (D3) 211) and may be separated from the substrate 200 by an insulator material (not shown). Each of the repeating, vertical levels, L1, L2, and L3 may include a plurality of discrete components (e.g., regions) to the laterally oriented access devices 230 and storage nodes including access line 207-1, 207-2, . . . , 207-Q connections and digit line 203-1, 203-2, . . . , 203-Q connections.

As shown in FIG. 2B, a plurality of horizontally oriented digit lines 203-1, 203-2, . . . , 203-Q extend in the direction (D1) 209. The plurality of horizontally oriented digit lines 203-1, 203-2, . . . , 203-Q may be arranged 3 along the direction (D3) 211.

Among each of the vertical levels, (L1) 213-1, (L2) 213-2, and (L3) 213-P, the horizontally oriented memory cells may be spaced apart from one another horizontally in the direction (D1) 209. However, as described in more detail below in connection with FIGS. 4A, et seq., the plurality of discrete components to the laterally oriented access devices 230 (e.g., first source/drain region 221 and second source/drain region 223 separated by a channel region 225), extending laterally in the direction (D2) 205, and the plurality of horizontally oriented digit lines 203-1, 203-2, . . . , 203-Q, extending laterally in the direction (D1) 209, may be formed within different vertical layers within each level. For example, the plurality of horizontally oriented digit lines 203-1, 203-2, . . . , 203-Q, extending in the direction (D1) 209, may be disposed on, and in electrical contact with, top surfaces of first source/drain regions 221 and orthogonal to laterally oriented access devices 230 extending laterally in the direction (D2) 205. In some embodiments, the plurality of horizontally oriented digit lines 203-1, 203-2, . . . , 203-Q, extending in the direction (D1) 209 are formed in a higher vertical layer, farther from the substrate 200, within a level (e.g., within level (L1)) than a layer in which the discrete components (e.g., first source/drain region 221 and second source/drain region 223 separated by a channel region 225) of the laterally oriented access device are formed. In some embodiments, the plurality of horizontally oriented digit lines 203-1, 203-2, . . . , 203-Q, extending in the direction (D1) 209, may be connected to the top surfaces of the first source/drain regions 221 directly and/or through additional contacts including metal silicides.

As shown in FIG. 2B, the access lines, 207-1, 207-2, . . . , 207-Q, extend in a vertical direction with respect to the substrate 200 (e.g., direction (D3) 211). Further, as shown in FIG. 2B, the access lines, 207-1, 207-2, . . . , 207-Q, in one sub cell array may be spaced apart from each other in the direction (D1) 209. The access lines, 207-1, 207-2, . . . , 207-Q, may extend vertically relative to the substrate 200 in the direction (D3) 211 between a pair of the laterally oriented access devices 230 extending laterally in the direction (D2) 205, but adjacent to each other on a level (e.g., first level (L1)) in the first direction (D1) 209. Each of the access lines, 207-1, 207-2, . . . , 207-Q, may vertically extend, in the direction (D3), on sidewalls of respective ones of the plurality of laterally oriented access devices 230 that are vertically stacked.

As an example, a first one of the vertically extending access lines (e.g., 207-1) may be adjacent a sidewall of a channel region 225 to a first one of the laterally oriented access devices 230 in the level (L1) 213-1, a sidewall of a channel region 225 of a first one of the laterally oriented access devices 230 in the level (L2) 213-2, and a sidewall of a channel region 225 a first one of the laterally oriented access devices 230 in the level (L3) 213-P, etc. Similarly, a second one of the vertically extending access lines (e.g., 207-2) may be adjacent a sidewall to a channel region 225 of a second one of the laterally oriented access devices 230 in the level (L1) 213-1, spaced apart from the first one of laterally oriented access devices 230 in the level (L1) 213-1 in the direction (D1) 209. And the second one of the vertically extending access lines (e.g., 207-2) may be adjacent a sidewall of a channel region 225 of a second one of the laterally oriented access devices 230 in the level (L2) 213-2, and a sidewall of a channel region 225 of a second one of the laterally oriented access devices 230 in the level (L3) 213-P, etc. Embodiments are not limited to a particular number of levels.

As shown in FIG. 1B, a first doped dielectric material 202 and a second doped dielectric material 206 may be utilized. The first doped dielectric material 202 can be adjacent to a gate and a semiconductor material (e.g., the first source/drain region 221). The second doped dielectric material 206 can be adjacent to the gate and a semiconductor material (e.g., the second source/drain region 223).

As shown in FIG. 2B, a body contact 295 may be formed along an end surface of the laterally oriented access devices 230 in each level (L1) 213-1, (L2) 213-2, and (L3) 213-P above the substrate 200. The body contact 295 may be connected to a body (e.g., body region) of the laterally oriented access devices 230 in each memory cell The body contact 295 may include a conductive material such as, for example, one of a doped semiconductor material, a conductive metal nitride, metal, and/or a metal-semiconductor compound.

Although not shown in FIG. 2B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

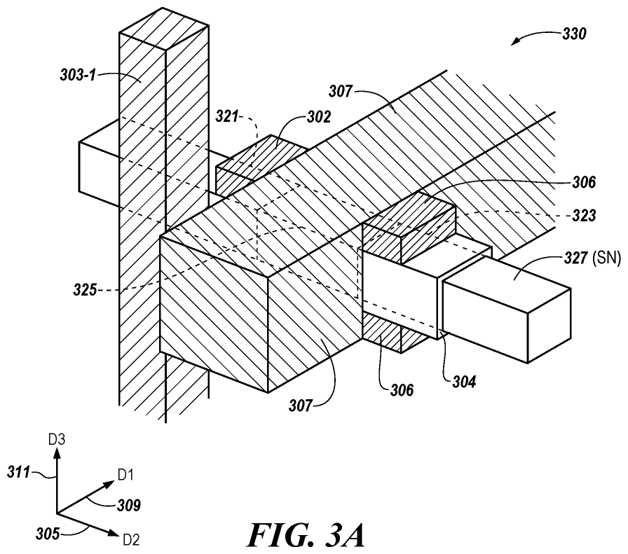

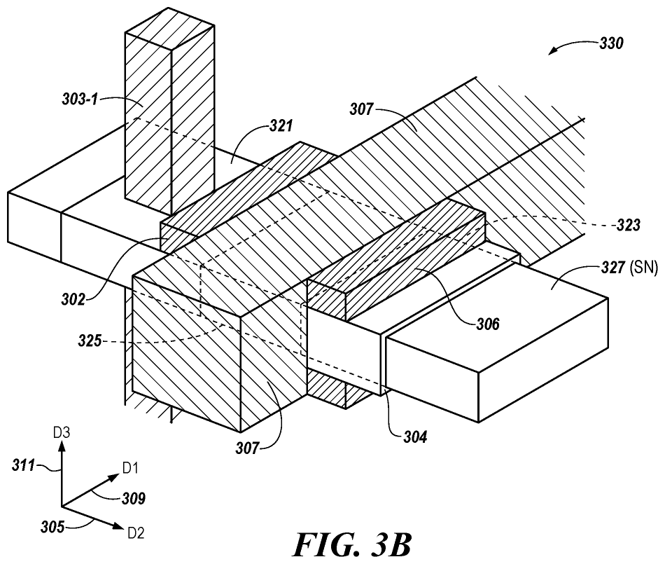

FIG. 3A illustrates a unit cell of the vertically stacked array of memory cells (e.g., within a sub cell array 101-2 in FIG. 1) according to some embodiments of the present disclosure. As shown in FIG. 3A, the first doped dielectric material 302 can be adjacent to a gate and a semiconductor material (e.g., the first source/drain region 321). The second doped dielectric material 306 can be adjacent to the gate and a semiconductor material (e.g., the second source/drain region 323).

As shown in the example embodiment of FIG. 3A, the first source/drain region 321 may occupy an upper portion in the body of the laterally oriented access devices 330. For example, the first source/drain region 321 may have a bottom surface within the body of the horizontally oriented access device 330 which is located higher, vertically in the direction (D3) 311 (which is normal to direction (D1) 309), than a bottom surface of the body of the laterally, horizontally oriented access device 330. As such, the laterally, horizontally oriented access device 330 may have a body portion which is below the first source/drain region 321 and is in electrical contact with the body contact. Further, as shown in the example embodiment of FIG. 3A, an access line, e.g., 307 may disposed on a top surface opposing and coupled to a channel region 325, separated therefrom by a gate dielectric 304. The gate dielectric material 304 may be formed, for example, by oxidizing a semiconductor material (e.g., oxidizing exposed surfaces of the semiconductor material). The gate dielectric material 304 may be adjacent the semiconductor material.

As shown in the example embodiment of FIG. 3A, a digit line 303-1 may be vertically extending in the direction (D3) 311 adjacent a sidewall of the first source/drain region 321 in the body to the horizontally oriented access devices 330 horizontally conducting between the first and the second source/drain regions 321 and 323 along the direction (D2) 305. In this embodiment, the vertically oriented digit line 303-1 is formed asymmetrically adjacent in electrical contact with the first source/drain regions 321. The digit line 303-1 may be formed as asymmetrically to reserve room for a body contact in the channel region 325.

FIG. 3B illustrates a unit cell of the vertically stacked array of memory cells (e.g., within a sub cell array 101-2 in FIG. 1) according to some embodiments of the present disclosure. As shown in FIG. 3B, the first doped dielectric material 302 can be adjacent to a gate and a semiconductor material (e.g., the first source/drain region 321). The second doped dielectric material 306 can be adjacent to the gate and a semiconductor material (e.g., the second source/drain region 323).

As shown in FIG. 3B, a digit line 303-1 may be vertically extending in the direction (D3) 311 adjacent a sidewall of the first source/drain region 321 in the body to the horizontally oriented access devices 330 horizontally conducting between the first and the second source/drain regions 321 and 323 along the direction (D2) 305. In this embodiment, the vertically oriented digit line 303-1 is formed symmetrically, in vertical alignment, in electrical contact with the first source/drain region 321. The digit line 303-1 may be formed in contact with an insulator material such that there is no body contact within channel region 325.

As shown in the example embodiment of FIG. 3B, the digit line 303-1 may be formed symmetrically within the first source/drain region 321 such that the first source/drain region 321 surrounds the digit line 303-1 all around. The first source/drain region 321 may occupy an upper portion in the body of the horizontally oriented access devices 330. For example, the first source/drain region 321 may have a bottom surface within the body of the horizontally oriented access device 330 which is located higher, vertically in the direction (D3) 311, than a bottom surface of the body of the laterally, horizontally oriented access device 330. As such, the laterally, horizontally oriented access device 330 may have a body portion which is below the first source/drain region 321 and is in contact with the body contact. An insulator material may fill the body contact such that the first source/drain region 321 may not be in electrical contact with channel region 325. Further, as shown in FIG. 3B, an access line 307-1 may disposed all around and coupled to a channel region 325, separated therefrom by a gate dielectric 304.

FIG. 4 is a cross-sectional view, at one stage of a semiconductor device fabrication process, for forming a vertical three-dimensional (3D) memory, and in accordance with a number of embodiments of the present disclosure.

In the example embodiment shown in the example of FIG. 4, the method comprises forming (e.g., epitaxially forming) alternating layers of a silicon germanium (SiGe) material, 430-1, 430-2, . . . , 430-N (which may be collectively referred to as epitaxially grown silicon germanium (SiGe) 430), and a silicon (Si) material, 432-1, 432-2, . . . , 432-N (which may be collectively referred to as epitaxially grown, single crystalline silicon (Si) material 432), in repeating iterations to form a vertical stack on a working surface of a substrate 400. In one embodiment, four layers of alternating, varying thickness (t) may be deposited to form a repeating tier to the repeating iterations. For example, the epitaxially grown silicon germanium (SiGe) 430 can be deposited to have a thickness (e.g., vertical height in the direction (D3)), in a range of thirty (30) nanometers (nm) to sixty (60) nm. In one embodiment, the silicon material 432 can be deposited to have a thickness (t2) in a range of five (5) nm to thirty (30) nm. Embodiments, however, are not limited to these examples. As shown in FIG. 4, a vertical direction 411 is illustrated as direction (D3) (e.g., z-direction) and 405 illustrated as direction (D2) (e.g., x-direction) in an x-y-z coordinate system.

In some embodiments, the epitaxially grown silicon germanium (SiGe), 430-1, 430-2, . . . , 430-N, may be an epitaxially grown mix of silicon and germanium. By way of example, and not by way of limitation, the epitaxially grown silicon germanium (SiGe) 430 may be grown on the substrate 400. Embodiments are not limited to these examples. The epitaxially grown, single crystalline silicon (Si) material, 432-1, 432-2, . . . , 432-N, may be a low doped, p-type (p−) epitaxially grown, single crystalline silicon (Si) material, or it may be undoped. The silicon material, 432-1, 432-2, . . . , 432-N, may also be formed by epitaxially growing on the epitaxially grown silicon germanium (SiGe) 430 material. After the epitaxially grown silicon germanium (SiGe) 430 has been formed, the silicon (Si) seed of the epitaxially grown silicon germanium (SiGe) material 430 may be used to epitaxially grown the single crystalline silicon (Si) material 432. Embodiments, however, are not limited to these examples.

The repeating iterations of alternating epitaxially grown silicon germanium (SiGe) 430-1, 430-2, . . . , 430-N layers, (SiGe) 431-1, 431-2, . . . , 431-N layers, epitaxially grown, single crystalline silicon (Si) material, 432-1, 432-2, . . . , 432-N layers, and epitaxially grown, single crystalline Si material, 433-1, 433-2, . . . , 433-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of a epitaxially grown silicon germanium (SiGe) and a epitaxially grown, single crystalline silicon (Si) material, in repeating iterations to form the vertical stack shown in FIG. 4.

The layers may occur in repeating iterations vertically. In the example of FIG. 4, four tiers, numbered 1, 2, 3, and 4 of the repeating iterations are shown. As an example, the stack may include: a first epitaxially grown silicon germanium (SiGe) 430-1, a first epitaxially grown, single crystalline silicon (Si) material 432-1, a second epitaxially grown silicon germanium (SiGe) 430-2, a second epitaxially grown, single crystalline silicon (Si) material 432-2, a second SiGe material 430-3, and a second epitaxially grown, single crystalline silicon (Si) material 432-3, in further repeating iterations. Embodiments, however, are not limited to this example and more or fewer repeating iterations may be included. A photolithographic mask 435 may be formed on the

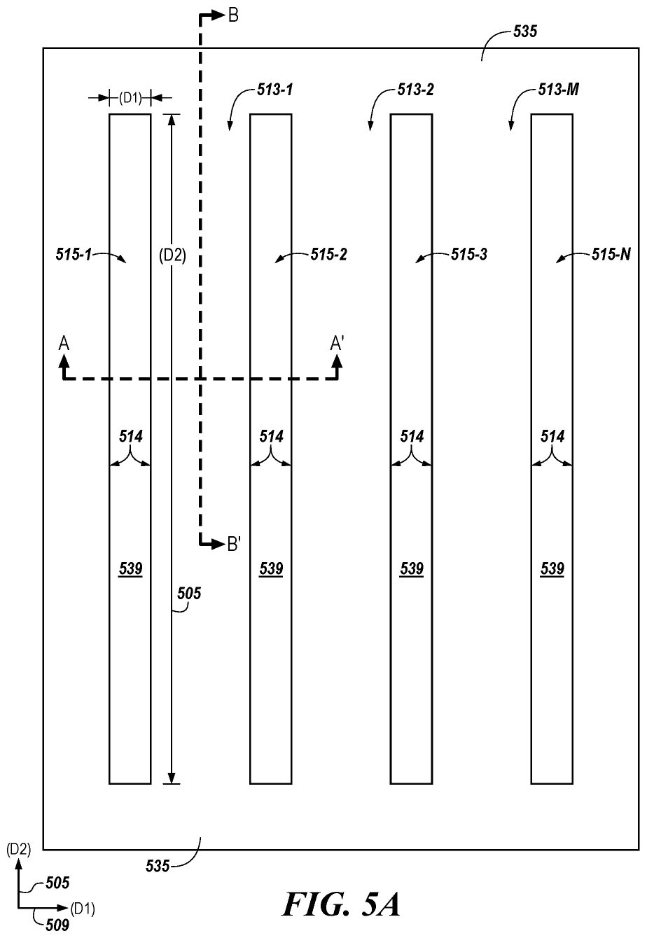

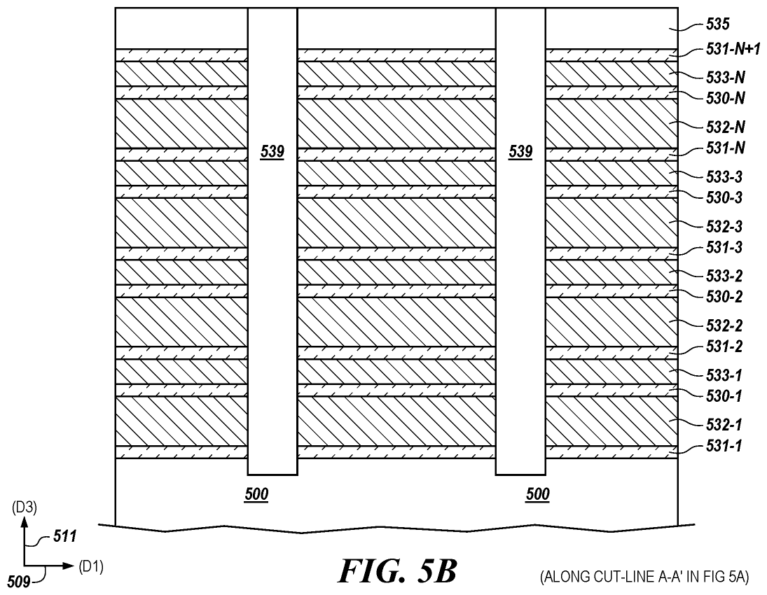

FIG. 5A illustrates an example method, at one stage of a semiconductor device fabrication process in accordance with a number of embodiments of the present disclosure. FIG. 5A illustrates a top down view of a semiconductor structure, at a particular stage of a semiconductor fabrication process, according to one or more embodiments. In the embodiment shown in FIG. 5A, the method comprises using an etchant process to form a plurality of first vertical openings 515-1, 515-2, 515-3, . . . , 513-N (e.g., lateral isolation openings), having a first horizontal direction (D1) 509 and a second horizontal direction (D2) 505, through the vertical stack to the substrate, a vertical direction (D3) 511 is also shown. In one example, as shown in FIG. 5A, the plurality of first vertical openings 515 are extending predominantly in the second horizontal direction (D2) 505 and may form elongated vertical, pillar columns 513-1, 513-2, . . . , 513-M (collectively and/or independently referred to as 513), with sidewalls 514 in the vertical stack. The plurality of first vertical openings 515 may be formed using photolithographic techniques to pattern a photolithographic mask 535 (e.g., to form a hard mask (HM)) on the vertical stack prior to etching the plurality of first vertical openings 515. Similar semiconductor process techniques may be used at other points of the semiconductor fabrication process described herein.

The openings 515 may be filled with a dielectric material 539 (e.g., a first dielectric material and/or a lateral isolation material). In one example, a spin on dielectric process may be used to fill the openings 515. In one embodiment, the dielectric material 539 may be an oxide material. However, embodiments are not so limited. The dielectric material 539 may provide isolation, such as laterally isolating portions of the array (e.g., cell isolation), for instance.

FIG. 5B is a cross sectional view, taken along cut-line A-A′ in FIG. 5A, showing a view of the semiconductor structure at one stage of a semiconductor device fabrication process. The cross sectional view shown in FIG. 5B shows the repeating iterations of alternating layers of a epitaxially grown silicon germanium (SiGe) 530 and a epitaxially grown, single crystalline silicon (Si) material 532 on a substrate 500 to form the vertical stack (e.g., as shown in FIG. 4).

As shown in FIG. 5B, a plurality of first vertical openings may be formed through the layers within the vertically stacked memory cells to expose vertical sidewalls in the vertical stack and form elongated vertical pillar columns and then filled with a dielectric material 539. These vertical openings may be formed through the repeating iterations of the epitaxially grown silicon germanium (SiGe) 530 and the epitaxially grown, single crystalline silicon (Si) material 532. As such, these vertical openings may be formed through a first epitaxially grown silicon germanium (SiGe) 530-1, a first epitaxially grown, single crystalline silicon (Si) material 532-1, a second epitaxially grown silicon germanium (SiGe) 530-2, a second epitaxially grown, single crystalline silicon (Si) material 532-2, a second SiGe material 530-3, and a second epitaxially grown, single crystalline silicon (Si) material 532-3, etc. Multiple vertical openings may be formed through the layers of materials.

As shown in FIG. 5B, a dielectric material 539, such as an oxide or other suitable spin on dielectric (SOD), may be deposited in the vertical openings, using a process such as CVD, to fill the first vertical openings. The dielectric material 539 may also be formed from a silicon nitride (Si₃N₄) material. In another example, the dielectric material 539 may include silicon oxy-nitride (SiOₓN_{y}), and/or combinations thereof. Embodiments are not limited to these examples. The plurality of vertical openings may be formed using photolithographic techniques to pattern a photolithographic mask 535 (e.g., to form a hard mask (HM)), on the vertical stack prior to etching the plurality of vertical openings. In one embodiment, hard mask 535 may be deposited over a epitaxially grown silicon germanium (SiGe) 530. Similar semiconductor process techniques may be used at other points of the semiconductor fabrication process described herein.

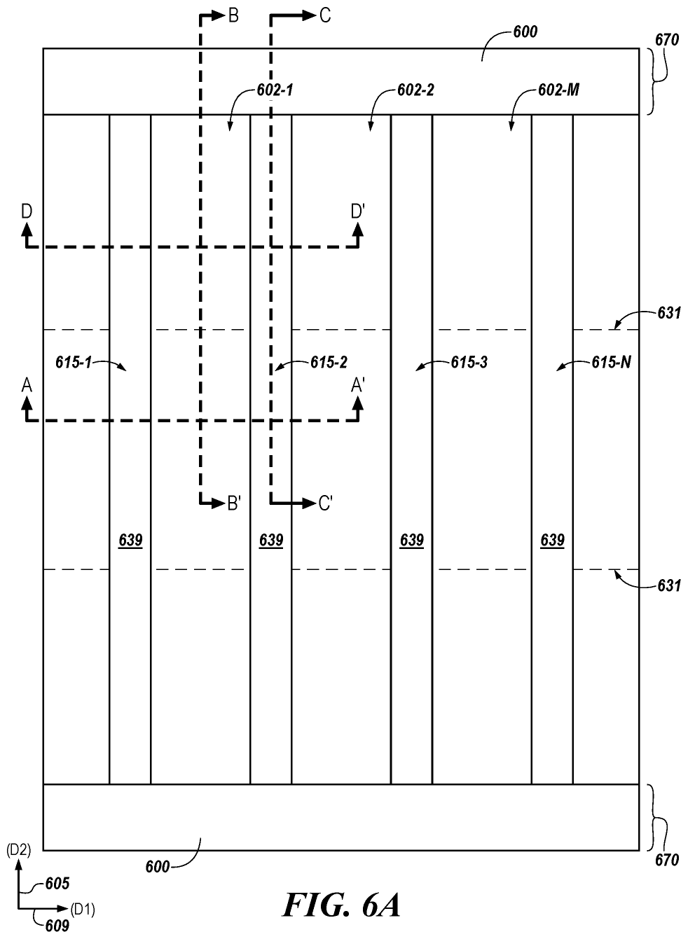

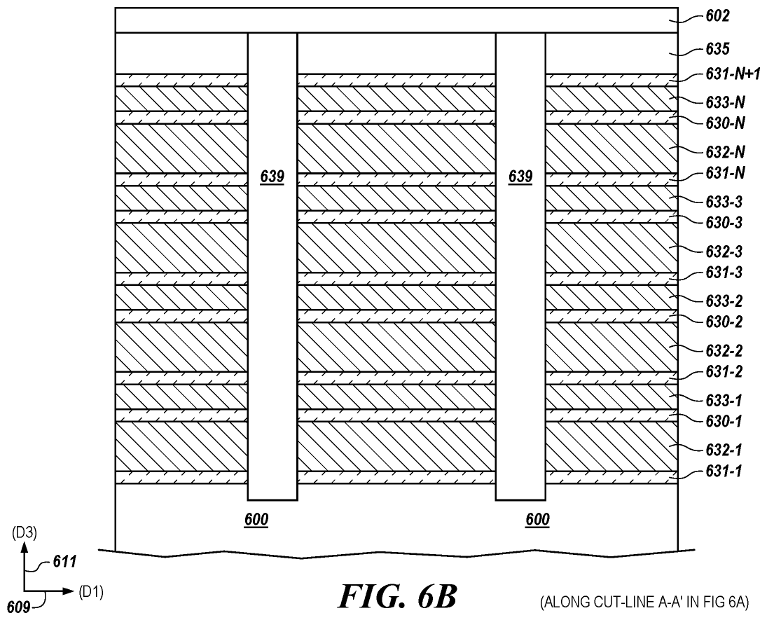

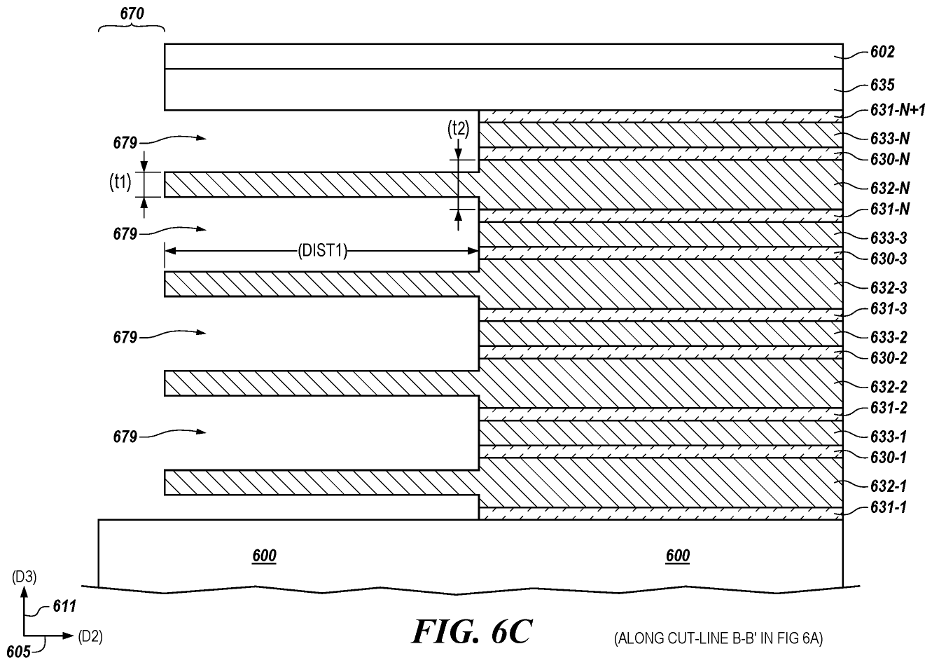

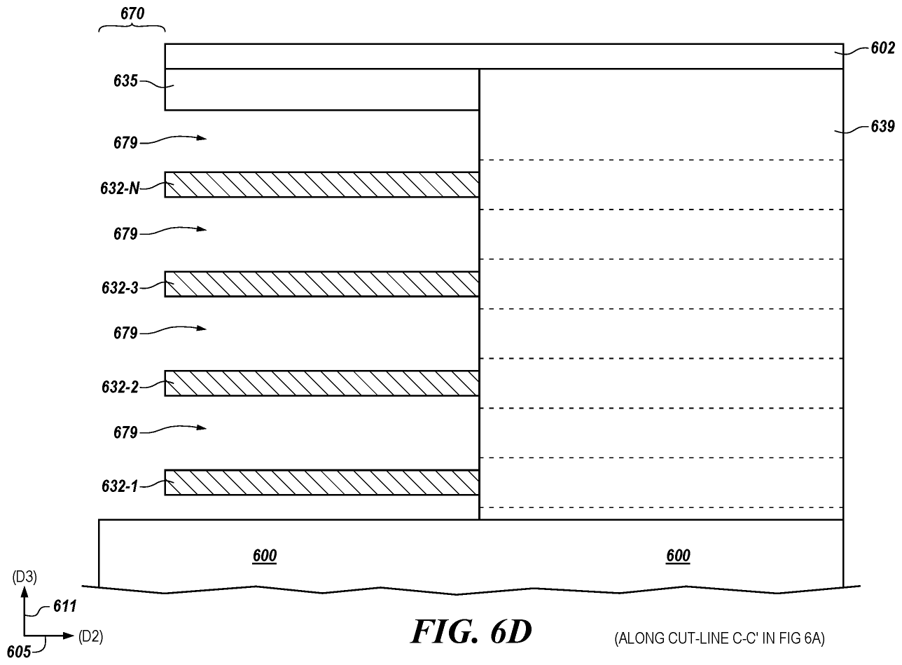

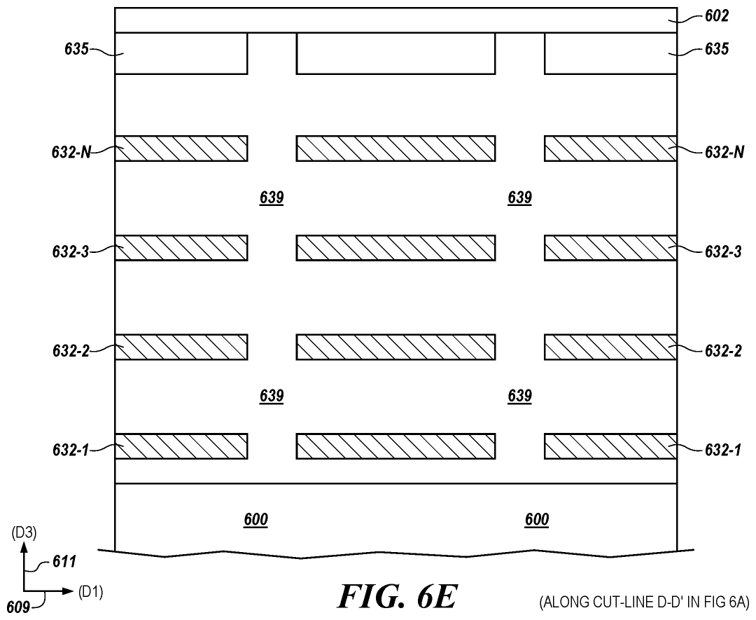

FIG. 6A illustrates an example method, at a stage of a semiconductor device fabrication process, in accordance with a number of embodiments of the present disclosure. FIG. 6A illustrates a top-down view of a semiconductor structure, at a point in time, in a semiconductor fabrication process, according to one or more embodiments.

As shown in FIG. 6A, the method can comprise using a photolithographic mask to pattern and form a second vertical opening 670 through the vertical stack and extending predominantly in the first horizontal direction to expose sidewalls adjacent a second region of the epitaxially grown silicon germanium (SiGe) and silicon (Si). The second vertical opening 670 (e.g., which may be referred to as a sidewall opening) may be etched through the hard mask 635 adjacent to where horizontal access devices are to be formed. And, multiple second vertical opening 670 may be formed through the layers of epitaxially grown silicon germanium (SiGe) and silicon (Si) using photolithographic techniques to pattern the hard mask 635 and expose those particular areas of the vertical stack.

FIG. 6B is a cross sectional view, taken along cut-line A-A′ in FIG. 6A, at one stage of a semiconductor device fabrication process in accordance with a number of embodiments of the present disclosure. The cross sectional view shown in FIG. 6B shows the repeating iterations of multiple, alternating layers of the epitaxially grown silicon germanium (SiGe) 630 and 631 and the epitaxially grown, single crystalline silicon (Si) material 632 and 633, on a substrate 600. In the example embodiment described herein four (4) alternating layers, 631, 632, 630, and 633, are shown making up a tier (e.g., tier 1 in FIG. 4) of the vertical stack. Embodiments, however, are not limited to this example. As shown in FIG. 6B, the dielectric material 639 may be formed, as previously mentioned.

FIG. 6C is a cross sectional view, taken along cut-line A-A′ in FIG. 6A, at one stage of a semiconductor device fabrication process in accordance with a number of embodiments of the present disclosure. FIG. 6C illustrates a cross sectional view, taken along cut-line B-B′ in FIG. 6A.

As noted above, FIG. 6C illustrates the method can comprise forming second vertical openings 670 through the vertical stack and extending predominantly in the first horizontal direction 609 to expose sidewalls adjacent a second region of the epitaxially grown silicon germanium (SiGe) 630 and 631 and the epitaxially grown, single crystalline silicon (Si) material 632 and 633. Forming the second vertical openings 670 through the vertical stack can comprise forming the second vertical openings 670 in vertical alignment with a location to form the horizontal access devices.

The cross-sectional view shown in FIG. 6C is illustrated as extending in the horizontal direction (D2) 605, left and right along the plane of the drawing sheet, along an axis of the repeating iterations of alternating layers of the epitaxially grown silicon germanium (SiGe) 630 and 631 and the epitaxially grown, single crystalline silicon (Si) material 632 and 633.

In the example of FIG. 6C, the epitaxially grown silicon germanium (SiGe) 630 and 631, and at least one sacrificial layer of the epitaxially grown, single crystalline silicon (Si) material 633, is selectively etched to form a plurality of first horizontal openings 679 extending a first distance (DIST 1) 676 from the second vertical openings 670. For example, an etchant may be flowed into the second vertical openings 670 to selectively etch the epitaxially grown silicon germanium (SiGe) 630 and 631, and at least one sacrificial layer of the epitaxially grown, single crystalline silicon (Si) material 633, and a portion of the epitaxially grown silicon (Si) 632. The etchant may selectively remove portions of all iterations of the epitaxially grown silicon germanium (SiGe) 630 and 631, and at least one sacrificial layer of the epitaxially grown, single crystalline silicon (Si) material 633, and a portion of the epitaxially grown silicon (Si) 632 within the stack according to a timed exhume process. As such, the etchant may primarily be selective to the epitaxially grown Si material 632 and selectively remove the epitaxially grown silicon germanium (SiGe) 630 and 631, and at least one sacrificial layer of the epitaxially grown, single crystalline silicon (Si) material 633, and a portion of the epitaxially grown silicon (Si) 632 a first distance (DIST 1) 676 within the stack.

However, embodiments are not so limited. For instance, one or more embodiments provide that each tier includes the epitaxially grown silicon germanium (e.g., 630 or 631) and the single crystalline silicon material 633 or the epitaxially grown silicon 632; in other words, each tier may include only two materials. In such embodiments, the epitaxially grown silicon germanium may be selectively etched to form the horizontal openings, similar to horizontal openings 679 discussed above.

The selective etchant process may occur in multiple steps to protect the structure and stabilize epitaxially grown, single crystalline silicon (Si) material 632. The selective etchant process may consist of one or more etch chemistries selected from an aqueous etch chemistry, a semi-aqueous etch chemistry, a vapor etch chemistry, or a plasma etch chemistries, among other possible selective etch chemistries. For example, a dry etch chemistry of oxygen (O₂) or O₂ and sulfur dioxide (SO₂) may be utilized. As another example, a dry etch chemistries of O₂ or of O₂ and nitrogen (N₂) may be used to selectively etch the epitaxially grown silicon germanium (SiGe) 630 and 631, and at least one sacrificial layer of the epitaxially grown, single crystalline silicon (Si) material 633, and a portion of the epitaxially grown silicon (Si) 632. Alternatively, or in addition, a selective etch to remove the epitaxially grown silicon germanium (SiGe) 630 and 631, and at least one sacrificial layer of the epitaxially grown, single crystalline silicon (Si) material 633, and a portion of the epitaxially grown silicon (Si) 632 may comprise a selective etch chemistry of phosphoric acid (H₃PO₄) or hydrogen fluoride (HF) and/or dissolving the epitaxially grown silicon germanium (SiGe) 730 using a selective solvent, among other possible etch chemistries or solvents.

Thus, the selective etchant process may be controlled by controlling time, composition of etchant gas, and etch rate of a reactant gas flowed into the second vertical openings 670 (e.g., rate, concentration, temperature, pressure, and time parameters).

The selective etch may be isotropic, but selective primarily to the epitaxially grown silicon (Si) material 632, removing only the epitaxially grown silicon germanium (SiGe) 630 and 631, and at least one sacrificial layer of the epitaxially grown, single crystalline silicon (Si) material 633, and a portion of the epitaxially grown silicon (Si) 632 in the timed exhume process. In one or more embodiments the selective etch may be performed according to a two-step exhumation process to first selectively remove the epitaxially grown silicon germanium (SiGe) 630 and 631 followed by a non-selective removal of the at least one sacrificial layer of the epitaxially grown, single crystalline silicon (Si) material 633, and a portion of the epitaxially grown silicon (Si) 632 to meet device target specifications. Thus, in one example embodiment, the selective etchant process may remove substantially all of the epitaxially grown silicon germanium (SiGe) 630 and 631, and at least one sacrificial layer of the epitaxially grown, single crystalline silicon (Si) material 633, and a portion of the epitaxially grown silicon (Si) 632, etching horizontally a first distance (DIST 1) 676 from the second vertical openings 670 according to the timed exhume process. Embodiments, however, are not limited to this example.

A controlled oxide lateral punch can be performed through the plurality of first vertical openings (e.g., 515 in FIG. 5A), between the access device regions and the first horizontal openings 679, to form continuous horizontal openings extending in the first horizontal direction (D1) 609 using a timed exhume process (e.g., selectively etching the first dielectric material 639). In some embodiments, the lateral punch may be a controlled etch process selective to the remaining, thinned epitaxially grown single crystalline silicon (Si) material 632 between separated epitaxially grown, remaining single crystalline silicon (Si) material 632 in the access device regions. In one embodiment, the remaining, thinned epitaxially grown single crystalline Si material 632 has a thickness (t1), from an original thickness (t2), in a range of approximately 50 to 250 angstroms (Å). In one embodiment, the original thickness (t2) is in a range of approximately 300 to 600 angstroms (Å). Selectively etching the first dielectric material 639 can be utilized to form segmented platforms of the silicon material 632 in the horizontal openings.

FIG. 6D illustrates a cross sectional view, taken along cut-line C-C′ in FIG. 6A, at one stage of a semiconductor device fabrication process in accordance with a number of embodiments of the present disclosure. The cross sectional view shown in FIG. 6D is illustrated extending in the horizontal direction (D2) 605, left and right in the plane of the drawing sheet, along an axis of the repeating iterations of multiple, alternating layers of the etched and removed epitaxially grown silicon germanium (SiGe) 630 and 631, and at least one sacrificial layer of the epitaxially grown, single crystalline silicon (Si) material 633, and a portion of the epitaxially grown silicon (Si) 632 forming second horizontal openings 679, and remaining epitaxially grown, single crystalline silicon (Si) material 632 having a thickness (t1) reduced from an original thickness, shown as (t2) in FIG. 6C.

At the left end of the drawing sheet is shown the repeating iterations of alternating layers of the etched epitaxially grown silicon germanium (SiGe) 630 and 631, and at least one sacrificial layer of the epitaxially grown, single crystalline silicon (Si) material 633, and a portion of the epitaxially grown silicon (Si) 632 forming second horizontal openings 679, and the remaining, thinned epitaxially grown, single crystalline silicon (Si) material 632. At the left end of the drawing sheet is shown the repeating iterations of alternating layers of the etched epitaxially grown silicon (SiGe), and etched areas where the first dielectric material has been removed to form continuous horizontal openings 643 in a first direction (D1) 609, separating the layers of remaining, thinned epitaxially grown, single crystalline silicon (Si) material 632. Second vertical opening 670 is shown adjacent a region of the now continuous horizontal openings 643. At the right hand of the drawing sheet, the first dielectric material 639 may be seen, separating access device and storage node regions in the direction (D1) 609. Dashed lines indicate the presence of the remaining un-etched, un-removed epitaxially grown silicon germanium (SiGe) 630 and 631, and full original deposition thicknesses (t2) of the epitaxially grown, single crystalline silicon (Si) material 632 and 632 and the first dielectric material 639, set into the plane of the drawing sheet, in the cross-sectional view, taken along cut-line C-C′ in FIG. 6A.

FIG. 6E illustrates a cross sectional view, taken along cut-line D-D′ in FIG. 6A, at one stage of a semiconductor device fabrication process in accordance with a number of embodiments of the present disclosure. The cross sectional view shown in FIG. 6E is illustrated, right to left in the plane of the drawing sheet, extending in the direction (D1) 609 along a cross section of the repeating iterations of alternating layers of remaining, thinned epitaxially grown, single crystalline silicon (Si) material 632, extending out of the plane of the drawing sheet from the first dielectric material 639. A hard mask 635 may be covered by second hard mask 637.

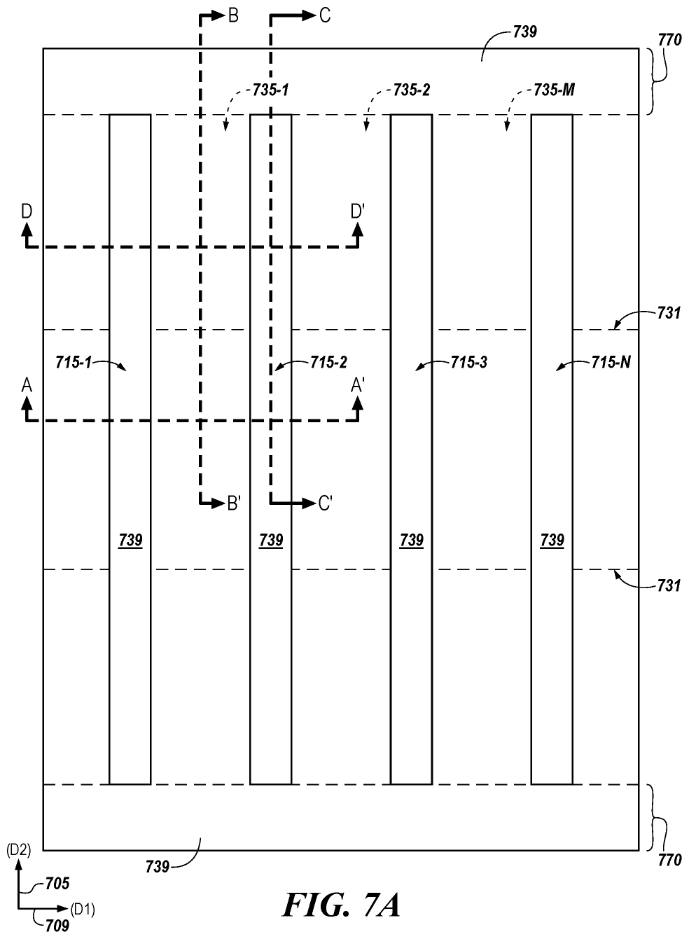

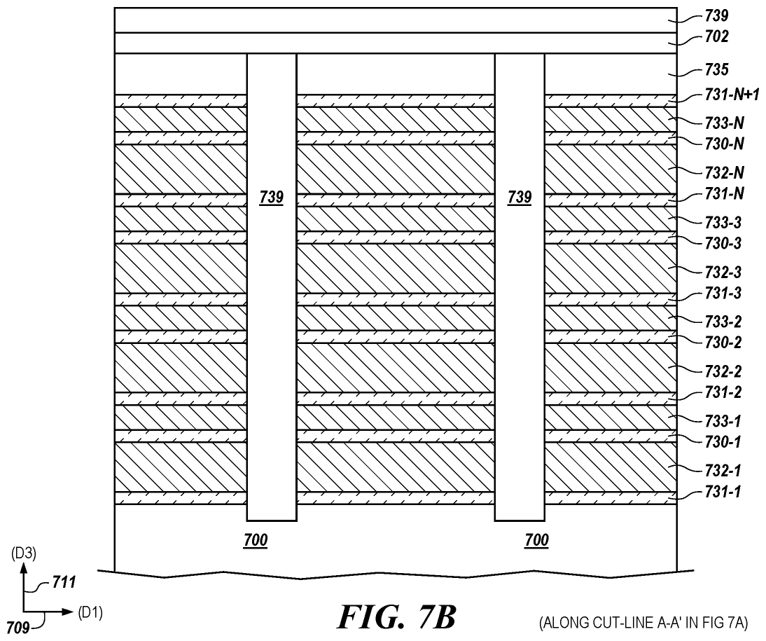

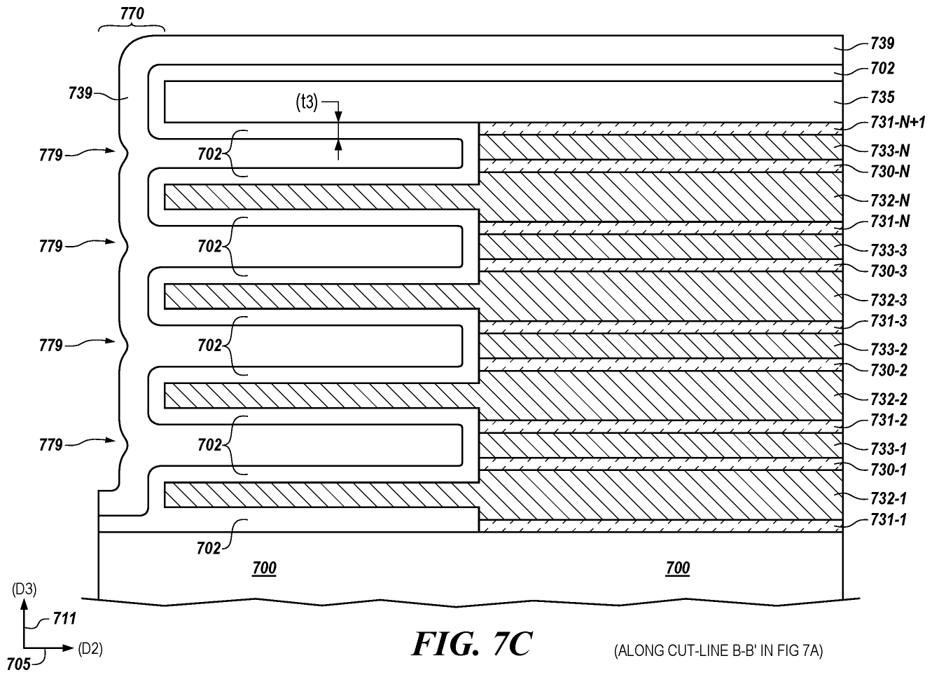

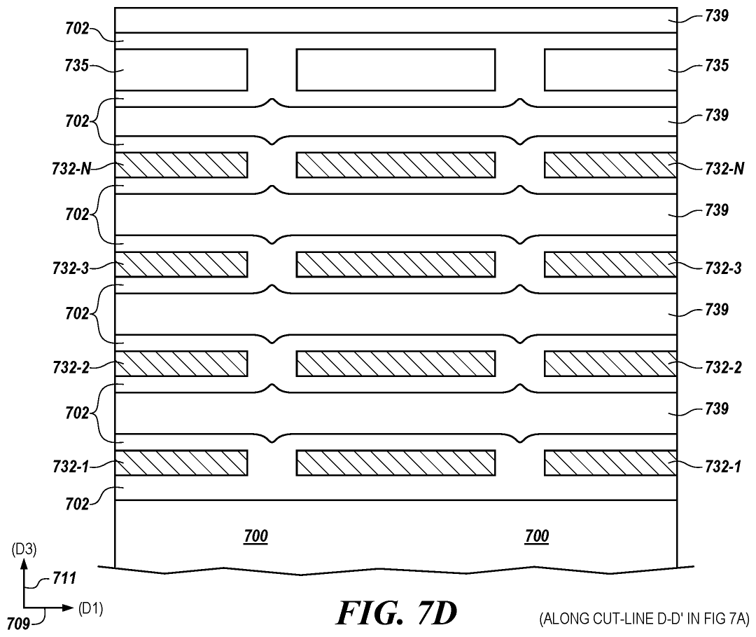

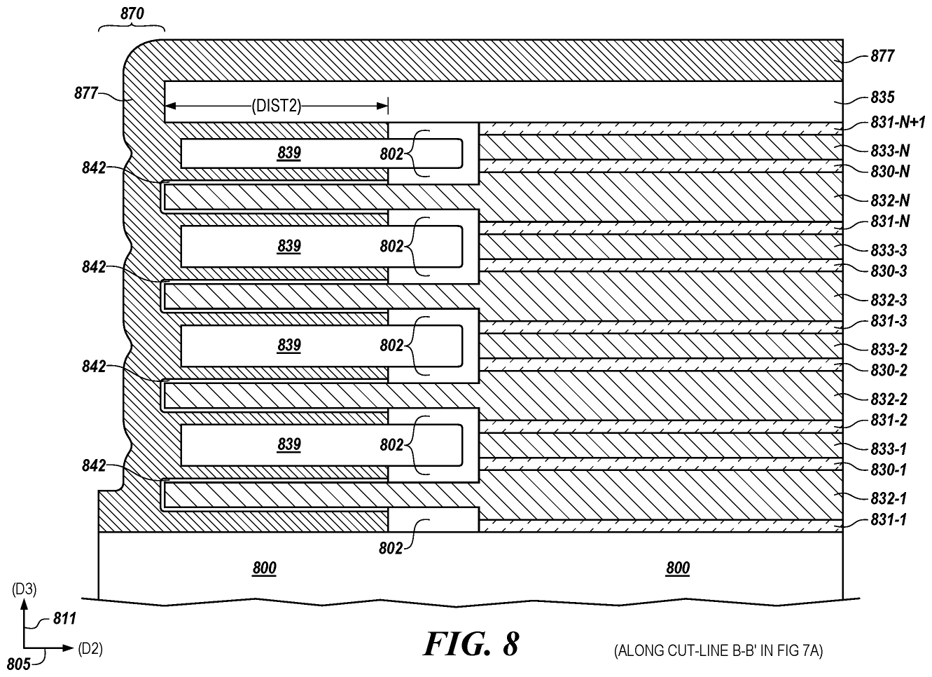

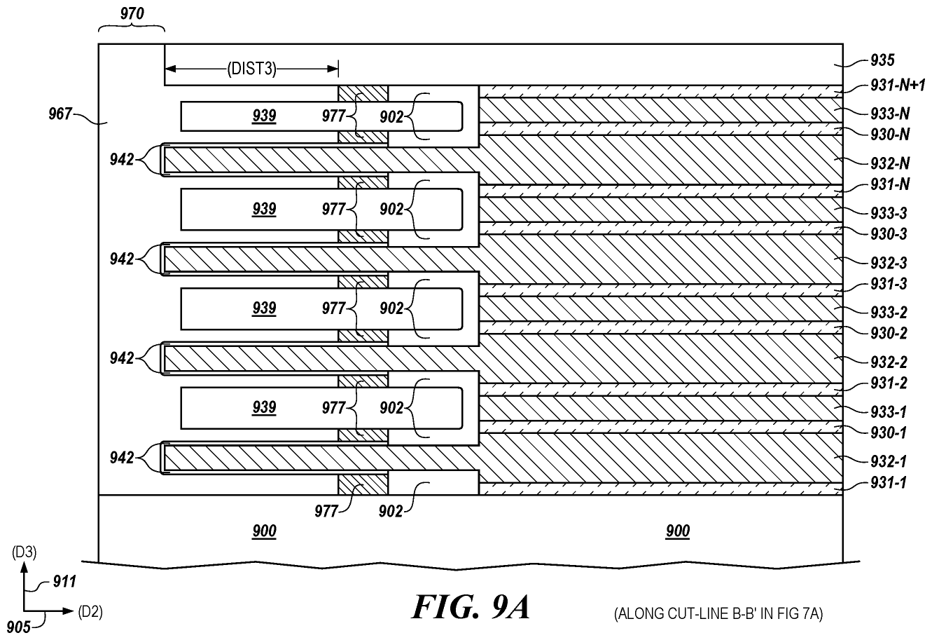

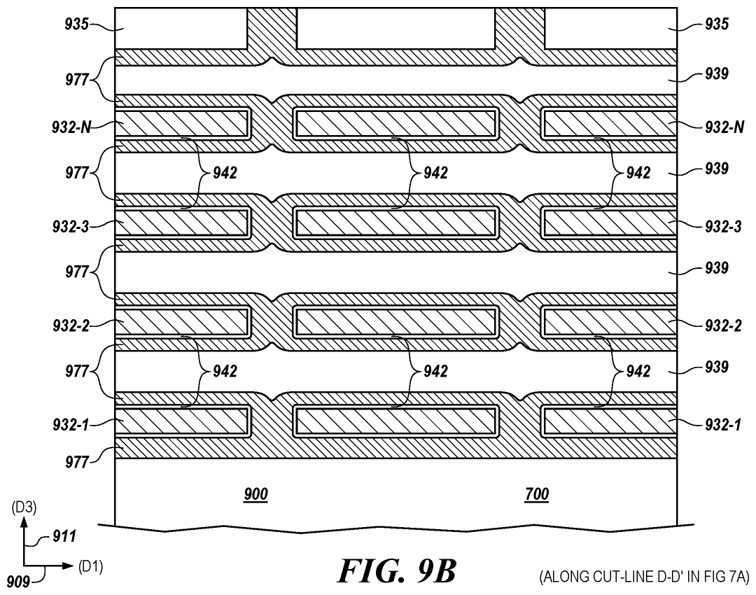

FIG. 7A illustrates an example method at one stage of a semiconductor device fabrication process in accordance with a number of embodiments of the present disclosure. FIG. 7A illustrates a top down view of a semiconductor structure.

In the embodiment of FIG. 7A, the semiconductor structure can comprise a newly deposited dielectric material 739 (e.g., a second dielectric material) that is deposited through the second vertical openings (670 in FIG. 6C) on exposed surfaces of the remaining, thinned epitaxially grown, single crystalline silicon (Si) material 732 within the first horizontal openings (679 in FIG. 6C). A portion of the unetched first dielectric material 739 may be seen in FIG. 7B.

FIG. 7B is a cross sectional view, taken along cut-line A-A′ in FIG. 7A, showing another view of the semiconductor structure at a particular time in the semiconductor device fabrication process. The cross-sectional view shown in FIG. 7B shows the repeating iterations of multiple, alternating layers of epitaxially grown silicon germanium (SiGe) 730 and 731 and the epitaxially grown, single crystalline silicon (Si) material 732 and 733, on a substrate 700.

As shown in FIG. 7B, a plurality of first vertical openings have already been formed through the layers within the vertically stacked memory cells to expose first vertical sidewalls (514 in FIG. 5A) in the vertical stack and filled with the first dielectric material 739. In FIGS. 5A-5B, the first vertical openings were formed through the repeating iterations of the epitaxially grown silicon germanium (SiGe) 730 and 731 and the epitaxially grown, single crystalline silicon (Si) material 732 and 733.

As shown in FIG. 7B, a first dielectric material 739, such as an oxide or other suitable spin on dielectric (SOD), is shown in the first vertical openings (515 in FIG. 5A), filling the first vertical openings. A hard mask 735 is shown over the vertical stack having dielectric material 739 deposited thereon. In some embodiments, as shown in the cross-sectional view of FIG. 7B, a third dielectric material 739 may be the a same type dielectric material as used for the first dielectric material. Embodiments, however, are not so limited.

FIG. 7C is a cross-sectional view, taken along cut-line B-B′ in FIG. 7A, showing another view of the semiconductor structure at this particular point in one example semiconductor device fabrication process in accordance with a number of embodiments of the present disclosure.

The epitaxially grown silicon germanium (SiGe) 730 and 731 and sacrificial layer of epitaxially grown silicon (Si) 733 have already been selectively etched isotropically in the direction (D2) 705, a distance in a timed exhume (DIST 1 in FIG. 6C), to form a plurality of first horizontal openings 779 in the first region separating layers of the remaining, thinned, epitaxially grown single crystalline (Si) material 732. A first doped dielectric material 702 can be deposited (e.g., conformally) in the first horizontal openings 779. In one embodiment, the first doped dielectric material is deposited using an atomic layer deposition (ALD) process. The first doped dielectric material 702 may be flowed into the second vertical opening 770 and first horizontal openings 779, from where sacrificial epitaxially grown silicon germanium (SiGe) material layers 630 and 631 (in FIG. 6C) and at least one, thinner sacrificial epitaxially grown single crystalline (Si) material layer (633 in FIG. 6C) was removed, to cover exposed surfaces of the remaining, thinned, epitaxially grown, single crystalline silicon (Si) material 732.

In one embodiment, the first doped dielectric material 702 may comprise a nitride material. In another embodiment, first doped dielectric material 702 may comprise a silicon nitride (Si₃N₄) material (also referred to herein as “SiN”). In another embodiment the first doped dielectric material 702 may include silicon dioxide (SiO₂) material. In another embodiment the first doped dielectric material 702 may comprise a silicon oxy-carbide (SiOxCy) material, and/or combinations thereof. In one embodiment, the first doped dielectric material 702 may include Al. As an example, aluminum or ammonia may be utilized to dope the first doped dielectric material 702. One or more embodiments provide that the first doped dielectric material 702 may have a fixed charge. One or more embodiments provide that the first doped dielectric material 702 may be an n-type material. One or more embodiments provide that the first doped dielectric material 702 may be an p-type material. However, embodiments are not limited to these examples.

While FIG. 7C illustrates the first doped dielectric material 702 as a single material, embodiments are not so limited. For instance, the first doped dielectric material may include a plurality of materials (e.g., a multi-layer film that provides an engineered fixed charge polarity and concentration). The first doped dielectric material may have a positive fixed charge. The first doped dielectric material may have a negative fixed charge.

In one embodiment, the first doped dielectric material 702 may be conformally deposited have a thickness (t3) of approximately 20 to 80 angstroms (Å), for instance.

As further shown in FIG. 7C, one or more embodiments provide that a dielectric material 739 (e.g., an insulating material such as an oxide material or a nitride material) may be deposited (e.g., conformally) on exposed surfaces of the first doped dialectic material 702. The third dielectric material 739 may be deposited to fill the plurality of first horizontal openings 779, and at least partially the second vertical opening 770, and to further provide a support, bridge-like structure to the remaining, thinned, epitaxially grown single crystalline (Si) material 732. In some embodiments, as shown in FIG. 7C, the third dielectric material 739 may be a same dielectric material as the first dielectric material and may further serve as a liner around the plurality of first horizontal openings 779. The third dielectric material 739 may be flowed into the second vertical opening 770 to cover exposed surfaces of the first doped dialectic material 702, and supporting the remaining, thinned, epitaxially grown, single crystalline silicon (Si) material 732 from where sacrificial epitaxially grown silicon germanium (SiGe) material layers 630 and 631 and at least one, thinner sacrificial epitaxially grown single crystalline (Si) material layer 733 was removed to form the plurality of first horizontal openings 779 within the stack.

FIG. 7D illustrates a cross sectional view, taken along cut-line D-D′ in FIG. 7A, showing another view of the semiconductor structure at a particular point. The cross-sectional view shown in FIG. 7D is illustrated, right to left in the plane of the drawing sheet, extending in the second direction (D2) 705 along a cross section of the repeating iterations of alternating layers of alternating layers of remaining, thinned, epitaxially grown, single crystalline silicon (Si) material 732, surrounded by first doped dielectric material 702 and spaced between layers of the vertical stack by the third dielectric material 739. A hard mask 735 may be covered by first doped dielectric material 702 and the third dielectric material 739. Thus, the third dielectric material 739 may also fill the spaces between the first doped dielectric material 702 and the cross section of repeating iterations of alternating layers of remaining, thinned epitaxially grown, single crystalline silicon (Si) material 732.

FIG. 8 illustrates an example method at one stage of a semiconductor device fabrication process in accordance with a number of embodiments of the present disclosure. As shown FIG. 8, a timed selective etch process can be performed, selectively etching the first doped dielectric material 802 a second distance (DIST 2) from the second vertical openings 870.

FIG. 8 illustrates a cross sectional view, taken along cut-line B-B′ in FIG. 7A, showing a view of the semiconductor structure at a particular point in a semiconductor device fabrication. The cross-sectional view shown in FIG. 8 shows the repeating iterations of alternating layers of the epitaxially grown silicon germanium (SiGe) 830 and 831 and the remaining, thinned epitaxially grown, single crystalline silicon (Si) material 732 (and un-etched, un-thinned epitaxially grown, single crystalline silicon (Si) material 732 that was not removed in the timed exhume described in FIG. 6C) on a substrate 700.

The cross-sectional view shown in FIG. 8 is illustrated extending in the horizontal direction (D2) 805, left and right along the plane of the drawing sheet, along an axis of the repeating iterations of alternating layers of the epitaxially grown silicon germanium (SiGe) 830 and 831 and the epitaxially grown, single crystalline silicon (Si) material 832 and 833. In some examples, first doped dielectric material 802 may be etched back a second distance (DIST 2) in a timed selective etch, exhume process. The distance (DIST 2) is the distance from the second vertical openings 870 to a remaining, unetched portion of the first doped dielectric material 802. In some embodiments, the first doped dielectric material 802 is etched back from the second vertical openings 870 the distance (DIST 2) in a range of approximately twenty-five (25) to seventy-five (75) nanometers (nm). The first doped dielectric material 802 may be selectively etched, being selective to the remaining, thinned epitaxially grown, single crystalline silicon (Si) material 832 and only partially thinning the third dielectric material 839, thus leaving the epitaxially grown, single crystalline silicon (Si) material 832 and portions of the third dielectric material 839 intact. As shown further in FIG. 8, a portion of the third dielectric material 839 has been removed with an additional selective etch of the first doped dielectric material 802 in the first horizontal openings (779 in FIG. 7C).

Further, as shown in FIG. 8 a gate dielectric material 842 may be formed on exposed surfaces of the remaining, thinned, epitaxially grown, single crystalline silicon (Si) material 832 to form horizontal access devices. In some embodiments the gate dielectric material may be an oxide material 842. The gate dielectric material 842 may be formed by oxidizing (e.g., a thermal oxidation process) a portion (e.g., exposed surfaces) of the single crystalline silicon (Si) material 832. One or more embodiments provide that the oxide material 842 can form gate all around (GAA) gate structures.

As shown in FIG. 8, a first conductive material 877 may be deposited on the gate dielectric material 842 to form gates. The first conductive material 877 may be deposited around the remaining, thinned, exposed epitaxially grown, single crystalline silicon (Si) material 832 such that the first conductive material 877 may have a top portion above the epitaxially grown, single crystalline silicon (Si) material 832 and a bottom portion below the epitaxially grown, single crystalline silicon (Si) material to form gate all around (GAA) gate structures. The first conductive material 877 may be conformally deposited into second vertical openings 870 and fill the continuous horizontal openings 843 up to the unetched portions of the third dielectric material 839 and the first doped dielectric material 802. The first conductive material 877 may be conformally deposited using a chemical vapor deposition (CVD) process, plasma enhanced CVD (PECVD), atomic layer deposition (ALD), or other suitable deposition process. Embodiments provide that the first doped dielectric material 802 is self-aligned with the first conductive material 877.

In some embodiments, the first conductive material, 877, may comprise one or more of a doped semiconductor material, e.g., doped silicon, doped germanium, etc. In some embodiments, the first conductive material 877 may comprise a conductive metal nitride material, e.g., titanium nitride, tantalum nitride, etc. In some embodiments, the first conductive material may comprise a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc, and/or some other combination thereof. The first conductive material 877 together with the gate dielectric material 842 may form horizontally oriented access lines (which also may be referred to a wordlines) opposing channel regions of the epitaxially grown, single crystalline silicon (Si) material.

FIG. 9A illustrates a cross sectional view, taken along cut-line B-B′ in FIG. 7A, showing a view of the semiconductor structure at a particular point in the semiconductor device fabrication process. The cross-sectional view shown in FIG. 9A is illustrated extending in the horizontal direction (D2) 905.

The first conductive material 977 was deposited on the gate dielectric material 942 and formed around the remaining, thinned, epitaxially grown, single crystalline silicon (Si) material 932, and is here recessed back to form gate all around (GAA) structures opposing only channel regions of the epitaxially grown, single crystalline silicon (Si) material 932, according to one or more embodiments of the present disclosure. The first conductive material 977, formed on the gate dielectric material 942, may be recessed and etched away from the second vertical opening 970. In some embodiments, the first conductive material 977 may be etched using an atomic layer etching (ALE) process. In some embodiments, the first conductive material 977 may be etched using an isotropic etch process. The first conductive material 977 may be selectively etched (e.g., leaving the gate dielectric material 942). The first conductive material 977 may be selectively etched in the second direction, in the continuous second horizontal openings (described above), a distance (DIST 3) in a range of twenty (20) to fifty (50) nanometers (nm) back from the second vertical opening 970. The first conductive material 977 may be selectively etched around the remaining, thinned epitaxially grown, single crystalline silicon (Si) material 932 and back into the continuous horizontal openings (described above). An ILD fill material 967 may be deposited into first vertical openings 970 and filling the continuous second horizontal openings up to the unetched portions of the gate dielectric material 942, the un-etched third dielectric material 939, and the first conductive material 977. The ILD fill material 967 may be conformally deposited using a chemical vapor deposition (CVD) process, plasma enhanced CVD (PECVD), atomic layer deposition (ALD), or other suitable deposition process.

As shown in 9A, one or more embodiments provide that the first doped dielectric material 902 is adjacent to the gate 977 and the semiconductor material 932.

FIG. 9B illustrates a cross sectional view, taken along cut-line D-D′ in FIG. 7A, showing a view of the semiconductor structure at a particular point in the semiconductor device fabrication process. The cross-sectional view shown in FIG. 9B is illustrated extending in the horizontal direction (D1) 909, left and right in the plane of the drawing sheet.

In FIG. 9B, first dielectric material 939 is shown spacing the arrays of vertically stacked memory cells, extending left and right along direction (D1) 909 in the plane of the drawings sheet, for a three-dimensional array of vertically oriented memory cells. Extending into and out from the plane of the drawing sheet is shown the repeating iterations of alternating layers of the remaining, thinned epitaxially grown, single crystalline silicon (Si) material 932 at the channel regions covered by the gate dielectric material 942, and covered in the continuous second horizontal openings (described above) in the direction (D1) 909 by the first conductive material 977. The first conductive material 977, formed on the gate dielectric material 942, was etched away from the second vertical opening 970. The first conductive material 977, formed on the gate dielectric material 942, was recessed back in the continuous horizontal openings extending in the second horizontal direction 905.

The first conductive material 977 is deposited on the gate dielectric material 942 and formed around the epitaxially grown, single crystalline silicon (Si) material 932 to form gate all around (GAA) structure. In FIG. 9B, the first conductive material, 977 is shown filling in the space in the second horizontal openings (described above) left by the etched first dielectric material 939.

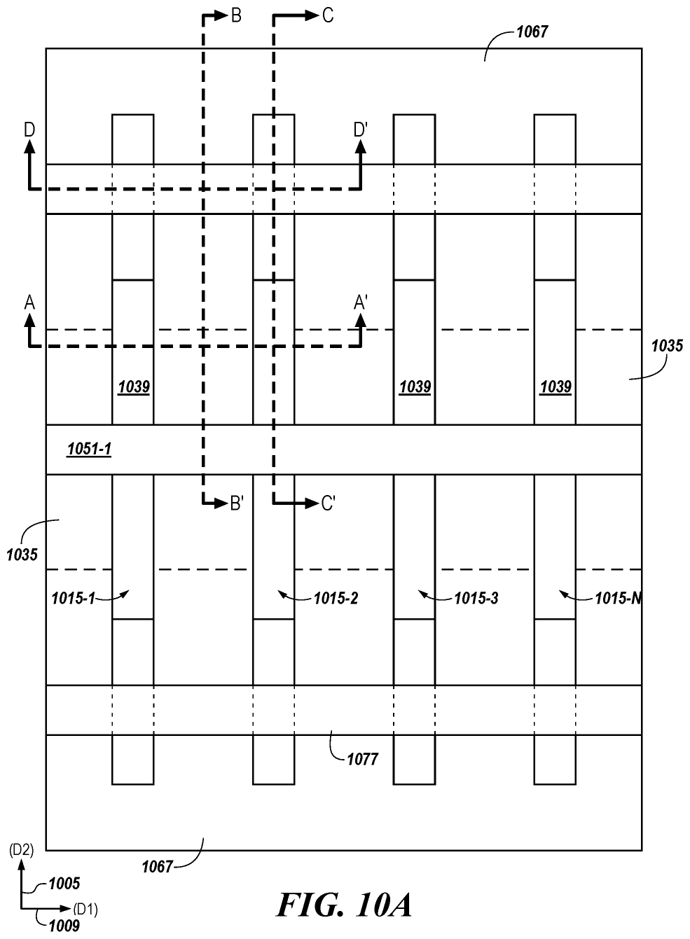

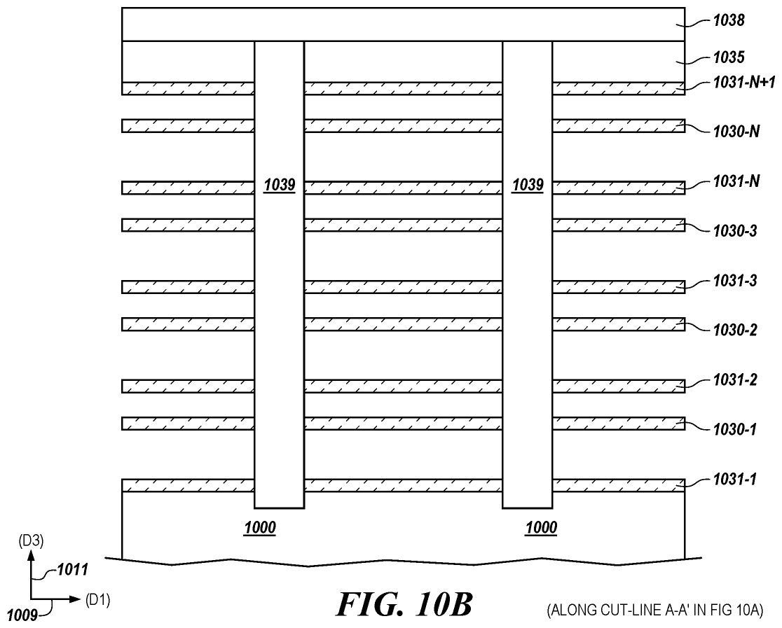

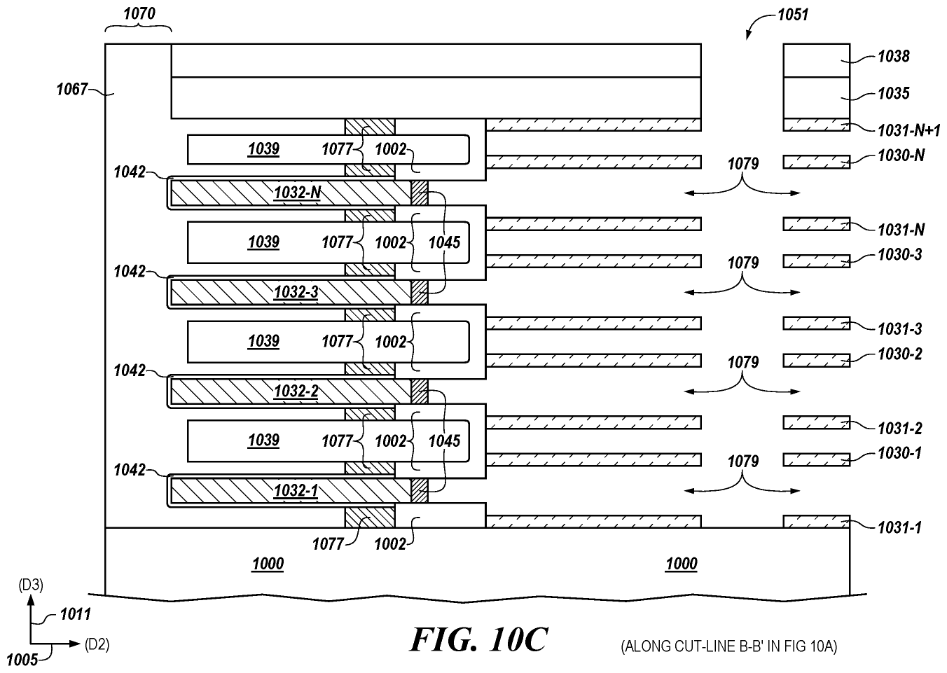

FIG. 10A illustrates an example method at one stage of a semiconductor device fabrication process in accordance with a number of embodiments of the present disclosure. FIG. 10A illustrates a top down view of the semiconductor structure according to one or more embodiments. In the example embodiment of FIG. 10A, the method comprises using a photolithographic process to pattern the photolithographic mask 1038 to form third vertical opening 1051 adjacent a second region of the repeating iterations of alternating layers of the epitaxially grown silicon germanium (SiGe) 1030 and 1031 and the epitaxially grown, single crystalline silicon (Si) material 1032 and 1033 to expose second vertical sidewalls in the stack. In FIGS. 10A-10C the epitaxially grown, single crystalline silicon (Si) material 1032 and 1033 is selectively etched in the second horizontal direction to form a plurality of second horizontal openings 1079 (shown in FIG. 10C), in which to form storage nodes, in a second region (e.g., storage node regions in the 3D vertical array of memory cells). Once the epitaxially grown, single crystalline silicon (Si) material 1032 and 1033 has been removed by selectively etching up to second source/drain regions 1045, adjacent channel regions for the horizontal access devices.

FIG. 10B illustrates a cross sectional view, taken along cut-line A-A′ in FIG. 10A in the storage node regions, showing a view of the semiconductor structure at a particular point in the semiconductor device fabrication process. The cross-sectional view shown in FIG. 10B is away from the plurality of separate, horizontal access lines, 1077 and shows repeating iterations of multiple, alternating layers of epitaxially grown silicon germanium (SiGe) 1030 and 1031 on a substrate 1000, where portions of the epitaxial silicon material 1032 and 1033 has been removed to form storage nodes. The plane of the drawing sheet, extending right and left, is in a direction (D1) 1009. In the example embodiment of FIG. 10B, the materials within the vertical stack, e.g., multiple, alternating layers of epitaxially grown silicon germanium (SiGe) 1030 and 1031 are extending into and out of the plane of the drawing sheet in direction (D2) and along an axis of orientation of the horizontal access devices and horizontal storage nodes of the arrays of vertically stacked memory cells of the three-dimensional memory.

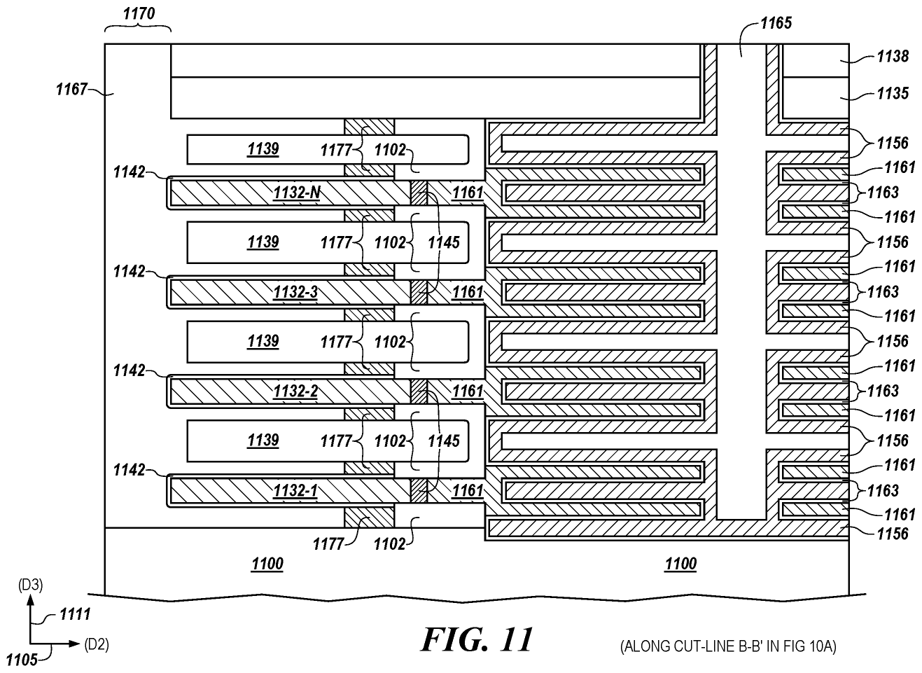

FIG. 10C illustrates a cross sectional view, taken along cut-line B-B′ in FIG. 10A, showing a view of the semiconductor structure at a particular point in the semiconductor device fabrication process. The cross sectional view shown in FIG. 10C is illustrated extending in the horizontal direction (D2) 1005, left and right along the plane of the drawing sheet. As shown in FIG. 10C, a third vertical opening 1051 has been formed through the repeating iterations of multiple, alternating layers of the epitaxially grown silicon germanium (SiGe) 1030 and 1031 and the epitaxially grown, single crystalline silicon (Si) material 1032 and 1033. The epitaxially grown, single crystalline silicon (Si) material 1032 in the second region (e.g., storage node region) is selectively etched to form the second horizontal openings 1079 in which to form storage nodes (shown in FIG. 11). In one example, an atomic layer etching (ALE) process is used to selectively etch the epitaxially grown, single crystalline silicon (Si) material 1032. In one embodiment selectively etching the epitaxially grown, single crystalline silicon (Si) material 1032 in the storage node region to form the second horizontal openings 1079 may be performed according to a timed exhume process. In one or more embodiments the first doped dielectric material 1002 can serve as an etch stop for the timed exhume, selective etch process.

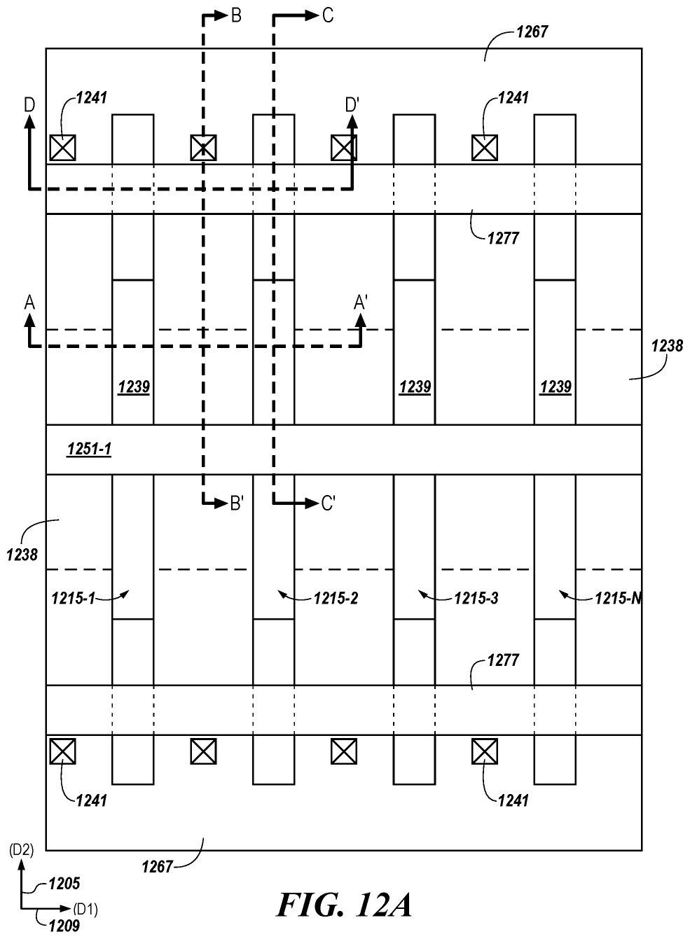

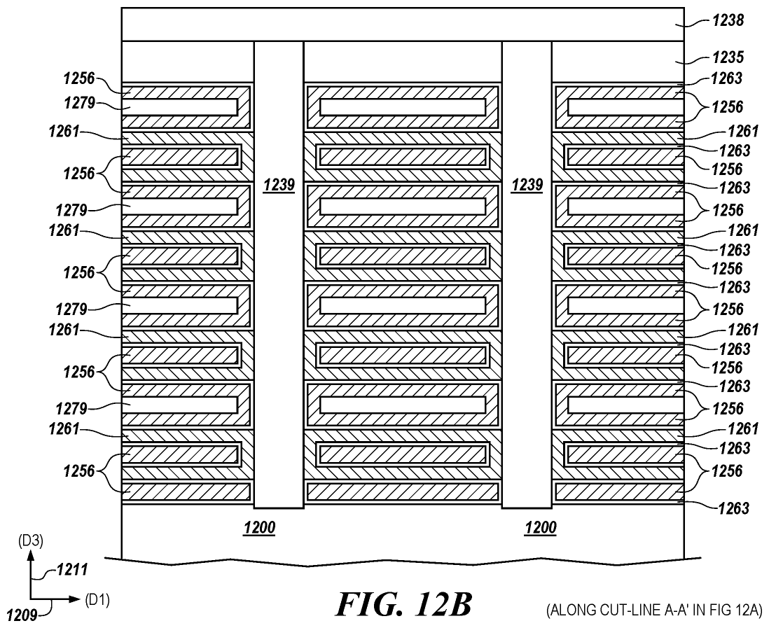

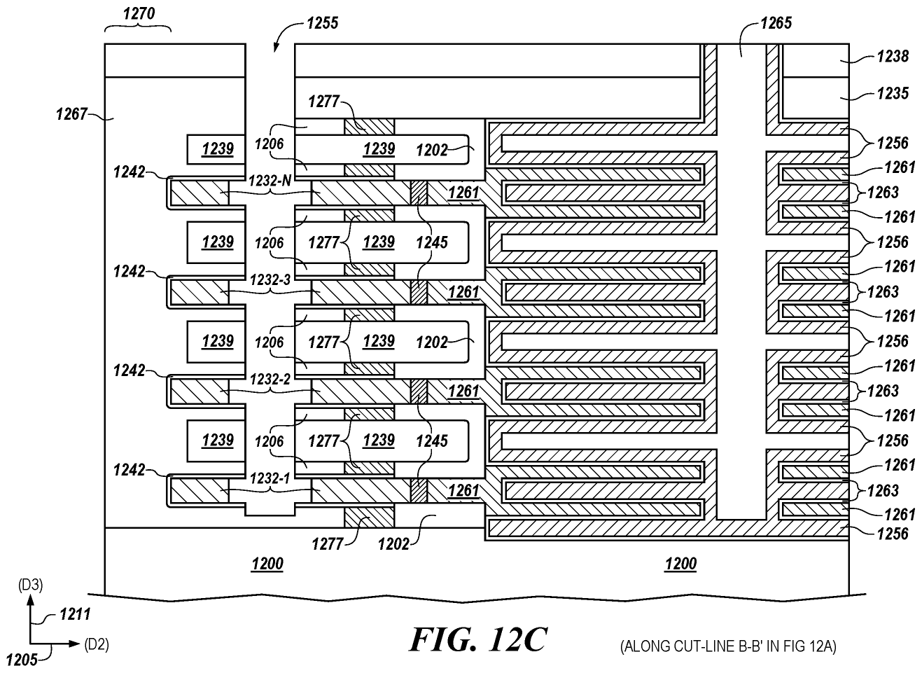

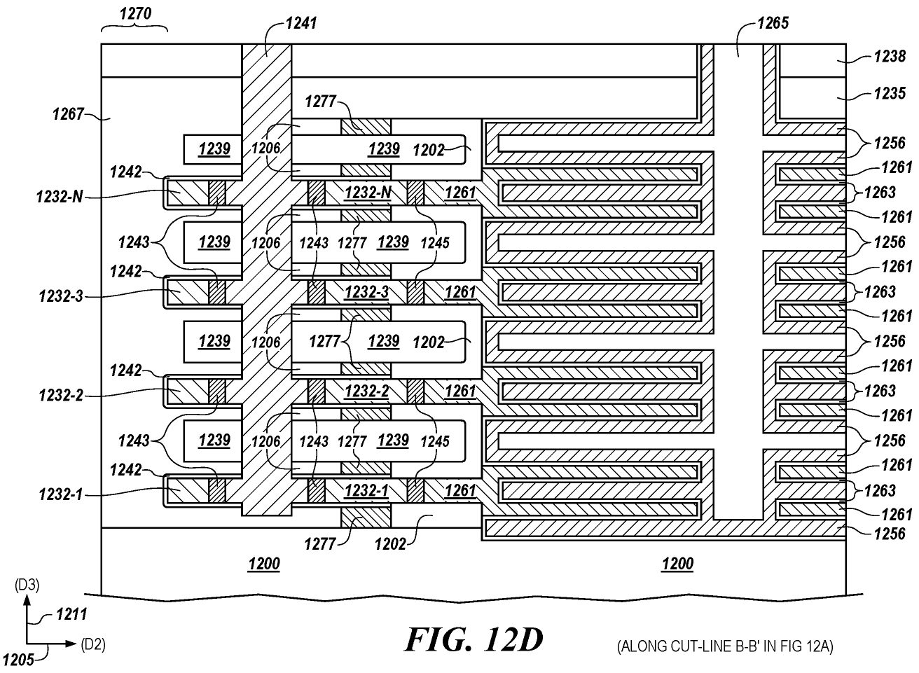

As is shown in FIG. 10C, a source/drain region 1045 may be present at a side surface portion of the epitaxially grown, single crystalline silicon (Si) material 1032. In some embodiments, the source/drain region 1045 may be a second source/drain region 1045 adjacent storage node regions and on one side of channel regions on an opposite side of channel regions from a first source/drain region (1243 in FIG. 12C) connecting to a digit line connection (described in FIGS. 12-14) to the horizontal access devices.

FIG. 11 illustrates a cross sectional view, taken along cut-line B-B′ in FIG. 10A, showing a view of the semiconductor structure at a particular point in the semiconductor device fabrication process. The cross-sectional view shown in FIG. 11 is illustrated extending in the horizontal direction (D2) 1105. And, as shown in FIG. 11, horizontally oriented storage nodes (e.g., capacitor cells) have been formed where the portions of the layers of epitaxially grown, single crystalline silicon (Si) material 1132 have been selectively etched and removed.

In FIG. 11, the storage nodes are illustrated as having been formed in this semiconductor fabrication process and first electrodes 1161 (e.g., bottom electrodes) to be coupled to second source/drain regions 1145 and second electrodes 1156 (e.g., top electrodes) to be coupled to a common electrode plane such as a ground plane, separated by cell dielectrics 1163, are shown. However, embodiments are not limited to this example. In other embodiments, the first electrodes 1161 coupled to second source/drain regions 1145 and second electrodes 1156 coupled to a common electrode plane separated by cell dielectrics 1163, may be formed subsequent to forming a first source/drain regions (1243 in FIG. 12C).

In the example embodiment of FIG. 11, the horizontally oriented storage nodes having the first electrodes 1161 and second electrodes 1156 are shown formed in a second horizontal opening, extending in direction (D2) 1105, left and right in the plane of the drawing sheet, a second distance from the third vertical opening, e.g., 1151 in FIG. 10B, formed in the vertical stack, and along an axis of orientation of the horizontal access devices and horizontal storage nodes of the arrays of vertically stacked memory cells of the three dimensional (3D) memory.

FIG. 12A illustrates an example method, at a stage of a semiconductor device fabrication process. FIG. 12A illustrates a top down view of a semiconductor structure, at a particular point in time according to one or more embodiments.

The method in FIG. 12A illustrates using one or more etchant processes to form a plurality of patterned fourth vertical openings 1255 in a vertical digit line region through the vertical stack, using a masked photolithographic process, and extending predominantly in the direction (D1) 1209. The one or more etchant processes form the plurality of patterned fourth vertical openings 1251, discussed below in connection with FIG. 12C, to expose second sidewalls in the repeating iterations of multiple, alternating layers of remaining, thinned epitaxially grown, single crystalline silicon (Si) material 1232 and the third dielectric material 1239 in FIG. 12C.

FIG. 12B illustrates a cross sectional view, taken along cut-line A-A′ in FIG. 12A. The cross-sectional view shown in FIG. 12B is away from the plurality of separate, horizontal access lines 1277, and shows repeating iterations of first electrodes 1261, cell dielectrics 1263, and top, common node electrodes 1256, on a substrate 1200. In FIG. 12B, the first electrodes 1261, coupled to source/drain regions (1245 in FIG. 12C) of horizontal access devices, and second electrodes 1256 are illustrated separated by a cell dielectric material 1263 extending into and out of the plane of the drawing sheet in second direction (D2) and along an axis of orientation of the horizontal access devices and horizontal storage nodes of the arrays of vertically stacked memory cells of the three-dimensional memory.

FIG. 12C illustrates a cross sectional view, taken along cut-line B-B′ in FIG. 12A, showing a view of the semiconductor structure at a particular point in the semiconductor device fabrication process.

As shown in FIG. 12C, a second doped dielectric material 1206 (e.g., a second electrostatic doping dielectric material) can be formed (e.g., by one or more processes discussed herein) adjacent to the conductive (e.g., gate) material 1277. Embodiments provide that the second doped dielectric material 1206 is self-aligned with the conductive material (e.g., gate) 1277. Embodiments provide that the second doped dielectric material 1206 adjacent to the gate and the semiconductor material 1232 (e.g., the second doped dielectric material can be separated from the semiconductor material by the gate dielectric, in other words the second doped dielectric material can be very near to the semiconductor material), wherein the respective second doped dielectric material is opposite to the respective first doped dielectric material relative to the respective gate

In one embodiment, the second doped dielectric material 1206 may comprise a nitride material. In another embodiment, second doped dielectric material 1206 may comprise a silicon nitride (Si₃N₄) material (also referred to herein as “SiN”). In another embodiment the second doped dielectric material 1206 may include silicon dioxide (SiO₂) material. In another embodiment second doped dielectric material 1206 may comprise a silicon oxy-carbide (SiOxCy) material, and/or combinations thereof. In one embodiment, the second doped dielectric material 1206 may include Al. As an example, Al or NH3 may be utilized to dope the second doped dielectric material 1206. One or more embodiments provide that the second doped dielectric material 1206 may have a fixed charge. One or more embodiments provide that the second doped dielectric material 1206 may be an n-type material. One or more embodiments provide that the second doped dielectric material 1206 may be an p-type material. However, embodiments are not limited to these examples. One or more embodiments provide that the second doped dielectric material 1206 and the first doped dielectric material 1202 are a same material. One or more embodiments provide that the second doped dielectric material 1206 and the first doped dielectric material 1202 are different materials.

In FIG. 12C, the horizontally oriented storage nodes are illustrated as having been formed; first electrodes 1261 coupled to source/drain regions of horizontal access devices, and second electrodes 1256 coupled to a common electrode plane such as a ground plane 1265, separated by cell dielectrics 1263, are shown. In this embodiment, a dual-sided capacitor is illustrated as an alternative to a single-sided capacitor. However, embodiments are not limited to this example. In FIG. 12C, the storage nodes having the first electrodes 1261 and second electrodes 1256 are shown formed in a horizontal opening, extending in direction (D2) 1205.

FIG. 12D illustrates a cross sectional view, taken along cut-line B-B′ in FIG. 12A, showing a view of the semiconductor structure at a particular point in the semiconductor device fabrication process. As shown in FIG. 12D, an etchant process has been used to form the plurality of patterned fourth vertical openings 1251, discussed above in connection with FIG. 12C, vertically through, and to expose second sidewalls in the repeating iterations of multiple, alternating layers of remaining, thinned epitaxially grown, single crystalline silicon (Si) material 1232, ILD material 1267, and the third dielectric material 1239.

As shown in FIG. 12D, a second conductive material 1241 may be deposited to form vertical digit lines. The second conductive material 1241 may be formed as a vertical digit line adjacent multiple, alternating layers of remaining, thinned epitaxially grown, single crystalline silicon (Si) material 1232. In particular, the second conductive material 1241 may form vertically oriented digit lines adjacent a location to form first source/drain regions. In the embodiment shown in FIG. 12D, the second conductive material 1241 may comprise a highly doped n-type poly silicon (Si) material, for instance.

In one embodiment, the second conductive material 1241 may be formed by gas phase doping a high energy gas phase dopant, such as phosphorus (P) atoms, as impurity dopants, at a high plasma energy such as PECVD to form a high concentration, n-type doped (n+) region within the fourth vertical opening 1255. For example, a highly phosphorus (P) doped (n+) poly-silicon germanium (SiGe) material may be deposited into the fourth vertical openings 1281 to form the second conductive material 1241. As shown in FIG. 12D, the second conductive material 1241 can be coupled to (e.g., contact) the first source/drain regions 1243.

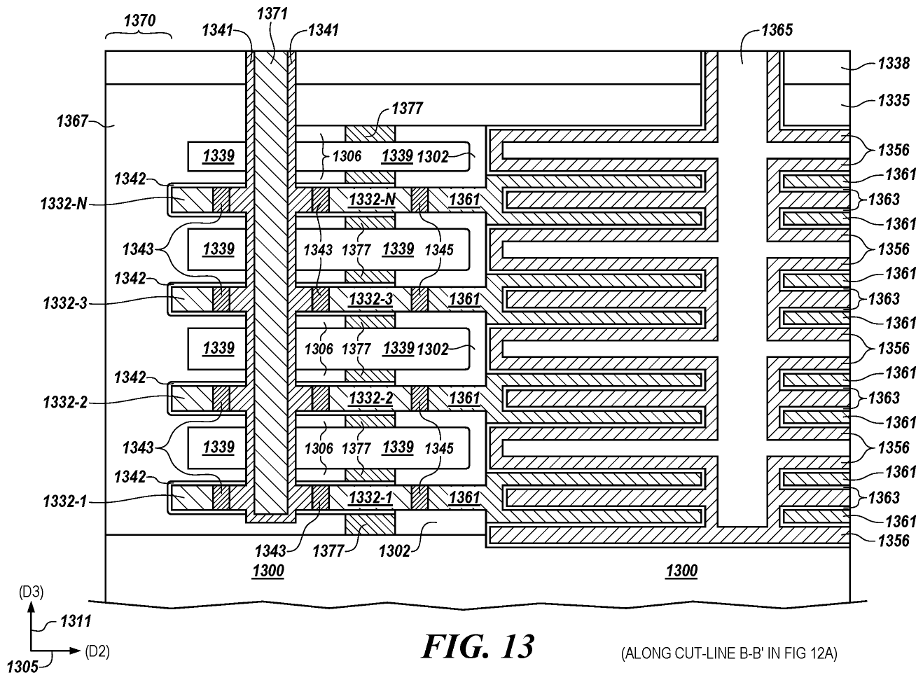

FIG. 13 illustrates a cross sectional view, taken along cut-line B-B′ in FIG. 12A, showing a view of the semiconductor structure at a point in the semiconductor device fabrication process. FIG. 13 provides an alternate embodiment of the present disclosure from that of FIG. 12D.

In the embodiment of FIG. 13, the second conductive material 1341 may be formed within second vertical openings (1255 in FIG. 12C). The second conductive material 1341 may be formed from a high concentration, n-type dopant. The high concentration, n-type dopant may be formed by depositing a polysilicon material onto the multiple, alternating layers of remaining, thinned epitaxially grown, single crystalline silicon (Si) material 1232.

As shown in the embodiment of FIG. 13, second conductive material 1371 (e.g., a metal material) may be deposited into the second vertical opening (1255 in FIG. 12C), within second conductive material 1341. In some embodiments, the metal material 1371 may comprise one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc, and/or some other combination thereof. The metal material 1371 coupled to the second conductive material 1341 may be formed vertically adjacent first conductive material 1377.

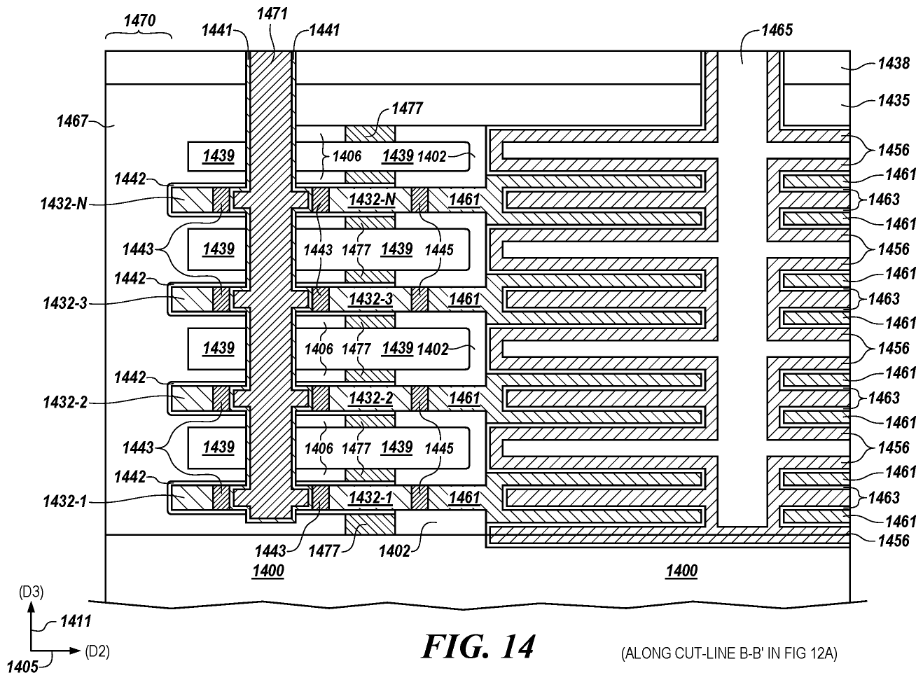

FIG. 14 illustrates a cross sectional view, taken along cut-line B-B′ in FIG. 12A, showing a view of the semiconductor structure at a point in one example semiconductor device fabrication process of another alternate embodiment of the present disclosure.

In the example embodiment of FIG. 14, the second conductive material 1441 may be formed within second vertical openings 1481. The second conductive material 1441 may be formed from a high concentration, n-type dopant. However, in this example embodiment, the high concentration, n-type dopant may be formed by depositing a highly phosphorus (P) doped (n+) poly-silicon germanium (SiGe) material onto the multiple, alternating layers of remaining, thinned epitaxially grown, single crystalline silicon (Si) material 1432.

As in the embodiment of FIG. 13, a metal material 1471 may be deposited into the second vertical opening (1255 in FIG. 12C), within second conductive material 1441. In some embodiments, the metal material 1471 may comprise one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc, and/or some other combination thereof. The metal material 1471 coupled to the second conductive material 1441 may be formed vertically adjacent first conductive material 1477.

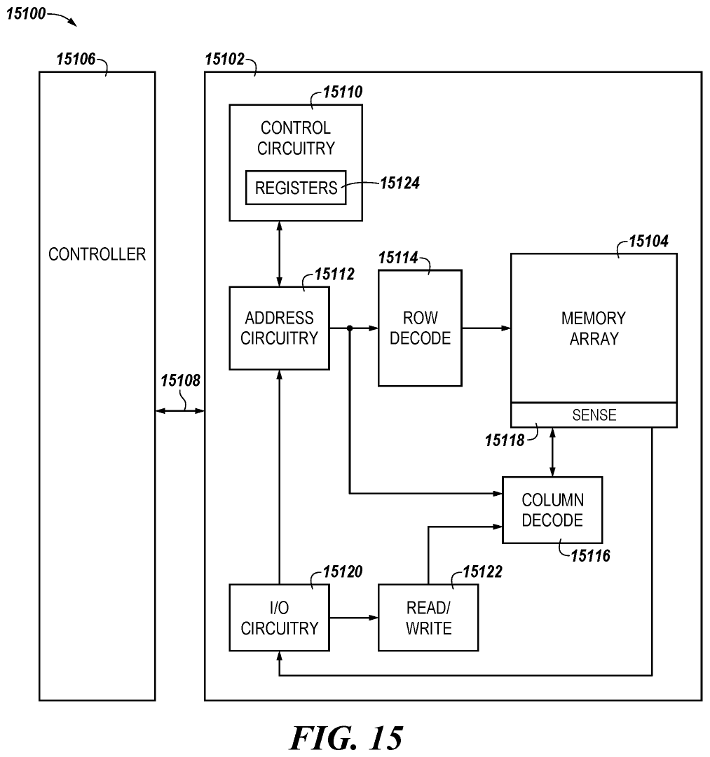

FIG. 15 is a block diagram of an apparatus in the form of a computing system 15100 including a memory device 15102 in accordance with a number of embodiments of the present disclosure. As used herein, a memory device 15102, a memory array 15104, and/or a host 15106, for example, might also be separately considered an “apparatus.” According to embodiments, the memory device 15102 may comprise at least one memory array 15104 with a memory cell, according to the embodiments described herein.

In this example, system 15100 includes a host 15106 coupled to memory device 15102 via an interface 15108. The computing system 15100 can be a personal laptop computer, a desktop computer, a digital camera, a mobile telephone, a memory card reader, or an Internet-of-Things (IoT) enabled device, among various other types of systems. Host 15106 can include a number of processing resources (e.g., one or more processors, microprocessors, or some other type of controlling circuitry) capable of accessing memory device 15102. The system 15100 can include separate integrated circuits, or both the host 15106 and the memory device 15102 can be on the same integrated circuit. For example, the host 15106 may be a system controller of a memory system comprising multiple memory devices 15102, with the system controller providing access to the respective memory devices 15102 by another processing resource such as a central processing unit (CPU).

In the example shown in FIG. 15, the host 15106 can be responsible for executing an operating system (OS) and/or various applications (e.g., processes) that can be loaded thereto (e.g., from memory device 15102 via controller 15106). The OS and/or various applications can be loaded from the memory device 15102 by providing access commands from the host 15106 to the memory device 15102 to access the data comprising the OS and/or the various applications. The host 15106 can also access data utilized by the OS and/or various applications by providing access commands to the memory device 15102 to retrieve said data utilized in the execution of the OS and/or the various applications.

For clarity, the system 15100 has been simplified to focus on features with particular relevance to the present disclosure. The memory array 15104 can be a DRAM array comprising at least one memory cell having a digit line and body contact formed according to the techniques described herein. For example, the memory array 15104 can be an unshielded DL 4F2 array such as a 3D-DRAM memory array. The array 15104 can comprise memory cells arranged in rows coupled by word lines (which may be referred to herein as access lines or select lines) and columns coupled by digit lines (which may be referred to herein as sense lines or data lines). Although a single array 15104 is shown in FIG. 15, embodiments are not so limited. For instance, memory device 15102 may include a number of arrays 15104 (e.g., a number of banks of DRAM cells).

The memory device 15102 includes address circuitry 15112 to latch address signals provided over an interface 15108. The interface can include, for example, a physical interface employing a suitable protocol (e.g., a data bus, an address bus, and a command bus, or a combined data/address/command bus). Such protocol may be custom or proprietary, or the interface 15108 may employ a standardized protocol, such as Peripheral Component Interconnect Express (PCIe), Gen-Z, CCIX, or the like. Address signals are received and decoded by a row decoder 15114 and a column decoder 15116 to access the memory array 15104. Data can be read from memory array 15104 by sensing voltage and/or current changes on the sense lines using sensing circuitry 15118. The sensing circuitry 15118 can comprise, for example, sense amplifiers that can read and latch a page (e.g., row) of data from the memory array 15104. The I/O circuitry 15120 can be used for bi-directional data communication with the host 15106 over the interface 15108. The read/write circuitry 15122 is used to write data to the memory array 15104 or read data from the memory array 15104. As an example, the circuitry 15122 can comprise various drivers, latch circuitry, etc.

Control circuitry 15110 decodes signals provided by the host 15110. The signals can be commands provided by the host. These signals can include chip enable signals, write enable signals, and address latch signals that are used to control operations performed on the memory array 15104, including data read operations, data write operations, and data erase operations. In various embodiments, the control circuitry 15110 is responsible for executing instructions from the host 15106. The control circuitry 15110 can comprise a state machine, a sequencer, and/or some other type of control circuitry, which may be implemented in the form of hardware, firmware, or software, or any combination of the three. The control circuitry 15110 can comprise a number of registers 15124. In some examples, the host 15106 can be a controller external to the memory device 15102. For example, the host 15106 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” an other element, the particular element can cover the other element, can be over the other element or lateral to the other element and/or can be in direct physical contact the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A three-dimensional memory device, comprising:
an array of vertically stacked memory cells, the array of vertically stacked memory cells, comprising:
access devices each respectively including:
a semiconductor material comprising a first source/drain region and a second source/drain region separated by a respective channel region, and a respective gate opposing the respective channel region and separated therefrom by a respective gate dielectric;
a respective first doped dielectric material adjacent to the respective gate and the respective semiconductor material;
a respective second doped dielectric material adjacent to the respective gate and the respective semiconductor material, wherein the respective second doped dielectric material is opposite to the respective first doped dielectric material relative to the respective gate;
storage nodes electrically coupled to the respective second source/drain regions of the access devices; and
digit lines electrically coupled to the second source/drain regions of the access devices.

2. The three-dimensional memory device of claim 1, wherein the respective first doped dielectric material is an n-type material.

3. The three-dimensional memory device of claim 1, wherein the respective first doped dielectric material is an p-type material.

4. The three-dimensional memory device of claim 2, wherein the respective second doped dielectric material is an n-type material.

5. The three-dimensional memory device of claim 3, wherein the respective second doped dielectric material is an p-type material.

6. The three-dimensional memory device of claim 1, wherein the respective first doped dielectric material is self-aligned to the respective gate.

7. The three-dimensional memory device of claim 1, wherein the respective second doped dielectric material is self-aligned to the respective gate.

8. The three-dimensional memory device of claim 1, wherein the respective semiconductor material comprises a crystalline silicon material.

9. The three-dimensional memory device of claim 1, wherein the respective semiconductor material comprises an undoped silicon material.

10. The three-dimensional memory device of claim 1, wherein the respective first doped dielectric material and the respective second doped dielectric material are a nitride material.

11. A method for forming an array of vertically stacked memory cells, the method comprising:
forming alternating layers of silicon germanium material and silicon material to form a vertical stack;
forming first vertical openings in the vertical stack;
forming a first dielectric material in the first vertical openings to laterally isolate portions of the array;
forming second vertical openings in the vertical stack to expose a sidewall of the vertical stack, wherein the second vertical openings are orthogonal to the first vertical openings;
selectively etching the silicon germanium material to form horizontal openings in the vertical stack;
removing a portion of the first dielectric material to form segmented platforms of the silicon material in the horizontal openings;
forming a first electrostatic doping dielectric material in the horizontal openings, wherein the first electrostatic doping dielectric material is adjacent to the segmented platforms of the silicon material;
removing a portion of the first electrostatic doping dielectric material in the horizontal openings;
forming a gate dielectric material adjacent the silicon material;
forming a conductive material to form a gate, wherein the conductive material is adjacent to the first electrostatic doping dielectric material;
recessing a portion of the conductive material; and
forming a second electrostatic doping dielectric material, wherein the second electrostatic doping dielectric material is adjacent to the conductive material and the gate dielectric material.

12. The method of claim 11, wherein the first electrostatic doping dielectric material and the second electrostatic doping dielectric material comprise a nitride material.

13. The method of claim 11, wherein the first dielectric material comprises an oxide material.

14. The method of claim 11, wherein the first electrostatic doping dielectric material and the second electrostatic doping dielectric material are different materials.

15. The method of claim 11, wherein forming the first electrostatic doping dielectric material comprises forming a plurality of films.

16. A method of forming an access device of a three-dimensional memory device, the method comprising:
forming alternating layers of silicon germanium material and silicon material;
removing a portion of the silicon germanium material in each of the respective alternating layers to form segmented platforms of the silicon material;
forming a first doped dielectric material adjacent to the segmented platforms of the silicon material;
forming an oxide material adjacent to the first doped dielectric material;
removing a portion of the first doped dielectric material;
forming a gate dielectric material adjacent the silicon material;
forming a gate material adjacent to a remaining portion of the first doped dielectric material and the gate dielectric material; and
forming a second doped dielectric material adjacent to the silicon material and the gate material.

17. The method of claim 16, wherein the first doped dielectric material is self-aligned to the gate material.

18. The method of claim 16, wherein the first doped dielectric material has a positive fixed charge.

19. The method of claim 16, wherein the first doped dielectric material has a negative fixed charge.

20. The method of claim 16, wherein the first doped dielectric material comprises aluminum or ammonia.
